(19) United States
(12) Patent Application Publication
(10) Pub. No.: US 2026/0247700 A1
(43) Pub. Date: Aug. 20, 2026

(54) SEMICONDUCTOR DEVICE

(71) Applicant: Samsung Electronics Co., Ltd., Suwon-si (KR)

(72) Inventors: Youngjin Yang, Suwon-si (KR); Wooseok Park, Suwon-si (KR); Myungil Kang, Suwon-si (KR); Hongshin Kim, Suwon-si (KR); Heejeong Jin, Suwon-si (KR); Doyoung Choi, Suwon-si (KR)

(21) Appl. No.: 19/330,292

(22) Filed: Sep. 16, 2025

(30) Foreign Application Priority Data
Feb. 18, 2025 (KR) 10-2025-0021026

(51) Int. Cl. H10D 84/83; H10D 62/10; H10D 64/23; H10D 64/27; H10D 84/01

(52) U.S. Cl. CPC H10D 84/833; H10D 64/518; H10D 84/0153; H10D 62/121; H10D 64/256

(57) ABSTRACT

A semiconductor device inventive concept comprises a first channel pattern and a second channel pattern spaced apart from each other on a substrate, a separation structure between the first channel pattern and the second channel pattern, and a gate electrode on the first channel pattern, the second channel pattern and the separation structure. The separation structure comprises a first pattern adjacent to the first channel pattern and the second channel pattern, and a second pattern between the first channel patterns and the second channel patterns. A portion of an upper surface of the first pattern is located at a higher level than an upper surface of a second pattern.

### CROSS-REFERENCE TO RELATED APPLICATION(S)

This U.S. non-provisional patent application claims priority under 35 U.S.C. § 119 to Korean Patent Application No. 10-2025-0021026, filed on Feb. 18, 2025, in the Korean Intellectual Property Office, the entire contents of which are hereby incorporated by reference.

### BACKGROUND

A semiconductor device may include an integrated circuit including metal-oxide-semiconductor field effect transistors (MOSFET). As the size of semiconductor devices has been reduced, the size of MOSFET has also been scaled down. Operating characteristics of semiconductor devices may be deteriorated as the MOSFET is scaled down. Thus, various researches are being conducted for semiconductor devices capable of overcoming limitations caused by a high integration density and of improving performance.

### SUMMARY

In general, the present disclosure is directed toward a semiconductor element having improved electrical characteristics.

According to some implementations, a semiconductor device comprising a first channel pattern and a second channel pattern spaced apart from each other on a substrate, a separation structure between the first channel pattern and the second channel pattern, and a gate electrode on the first channel pattern, the second channel pattern and the separation structure, wherein the separation structure includes a first pattern adjacent to the first channel pattern and the second channel pattern, and a second pattern between the first channel patterns and the second channel patterns, and a portion of an upper surface of the first pattern is located at a higher level than an upper surface of a second pattern.

According to some implementations, the present disclosure is directed to a semiconductor device comprising active patterns on a substrate, channel patterns each including a plurality of semiconductor patterns on the active patterns, a separation structure between the channel patterns, a gate electrode on the channel patterns and the separation structure, a first gate cutting pattern overlapping the separation structure, and a second gate cutting pattern spaced apart from the first gate cutting pattern and penetrating the gate electrode, wherein the separation structure includes a first pattern adjacent to the channel patterns and a second pattern spaced apart the channel patterns, and an uppermost surface of the first pattern is coplanar with a upper surface of the gate electrode.

According to some implementations, the present disclosure is directed to a semiconductor device comprising a first active pattern and a second active pattern spaced apart from each other on a substrate, first channel patterns on the first active pattern and second channel patterns on the second active pattern, first source/drain patterns between the first channel patterns and second source/drain pattern between the second channel patterns, separation structures between the first and second channel patterns which are adjacent in a first direction, gate electrodes on the first and second channels patterns and the separation structures, gate capping patterns on the gate electrodes, a first gate cutting pattern on at least one of the separation structures, and a second gate cutting pattern spaced apart from the separation structures and penetrating the gate electrodes, wherein each of the separation structures includes a first pattern and a second pattern filling an inside of the first pattern, and a portion of the first patterns further extends onto the second pattern.

According to some implementations, the present disclosure is directed to a method for manufacturing a semiconductor device comprising forming channel patterns on active patterns, forming a separation structure between the channel patterns, forming a gate electrode on the channel patterns and the separation structure, and forming a gate cutting pattern penetrating the gate electrode and in contact with the separation structure, wherein the separation structure includes a first pattern adjacent to the channel patterns and a second pattern in the first pattern, and a portion of the first pattern further extends onto the second pattern.

According to some implementations, the present disclosure is directed to a method for manufacturing a semiconductor device comprising forming the separation structure may include forming a first layer and a second layer on the channel patterns.

According to some implementations, the present disclosure is directed to a method for manufacturing a semiconductor device in which the first pattern may be formed from the first layer, and the second pattern is formed form the second layer.

According to some implementations, the present disclosure is directed to a method for manufacturing a semiconductor device in which each of the channel patterns may include a plurality of semiconductor patterns, and the method further comprising forming sacrificial patterns between the plurality of semiconductor patterns.

According to some implementations, the present disclosure is directed to a method for manufacturing a semiconductor device in which the sacrificial patterns may include a material having an etching selectivity with respect to the first pattern and the second pattern.

According to some implementations, the present disclosure is directed to a method for manufacturing a semiconductor device in which the gate cutting pattern may be formed by the portion of the first pattern in a self-aligned manner.

According to some implementations, the present disclosure is directed to a method for manufacturing a semiconductor device comprising forming a gate insulating layer covering the channel patterns between forming the channel patterns and forming the separation structure.

### BRIEF DESCRIPTION OF THE DRAWINGS

Example implementations will be more clearly understood from the following detailed explanations, taken in conjunction with the accompanying drawings.

FIG. 1 is a plan view illustrating an example of a semiconductor device according to some implementations.

FIGS. 2A, 2B, 2C, 2D, and 2E are cross-sectional views taken along line A-A′, line B-B′, line C-C′, line D-D′, and line E-E′ in FIG. 1 according to some implementations.

FIGS. 3A, 3B, 3C, 3D, and 3E are enlarged views for illustrating an example of a portion of a semiconductor device according to some implementations.

FIGS. 4A, 4B, 5A, 5B, 5C, 5D, 6A, 6B, 6C, 7A, 7B, 7C, 8A, 8B, 8C, 9A, 9B, 9C, 10A, 10B, 10C, 11A, 11B, 11C, 12A, 12B, and 12C are diagrams illustrating an example of a method of manufacturing a semiconductor device according to some implementations.

### DETAILED DESCRIPTION

Hereinafter, example implementations will be described in detail with reference to the accompanying drawings.

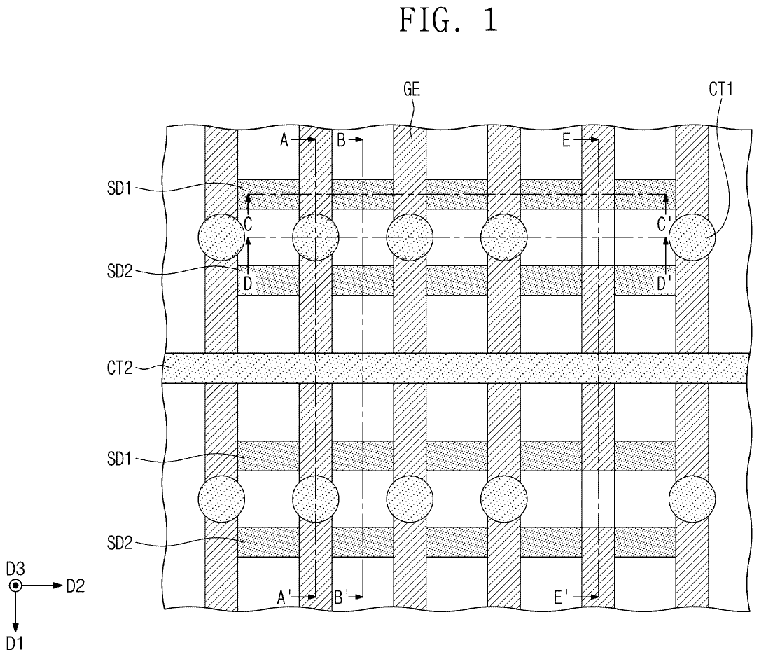

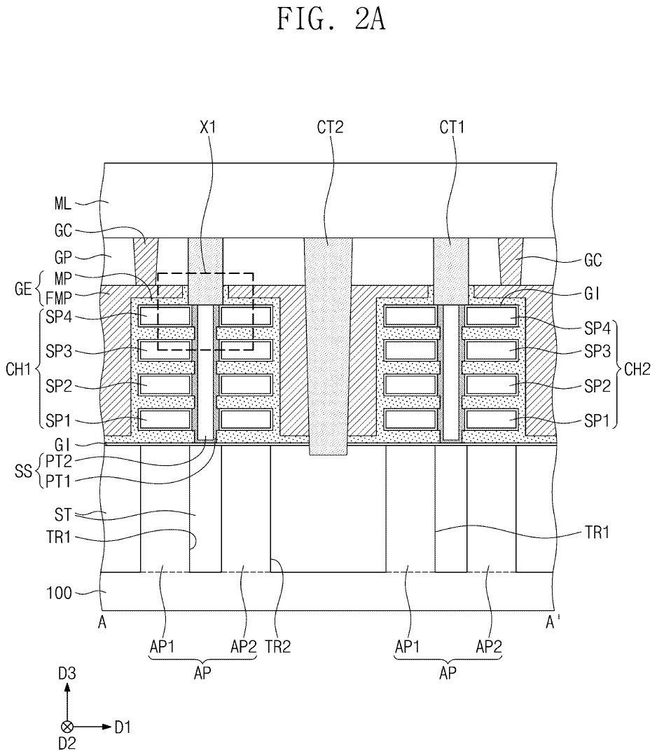

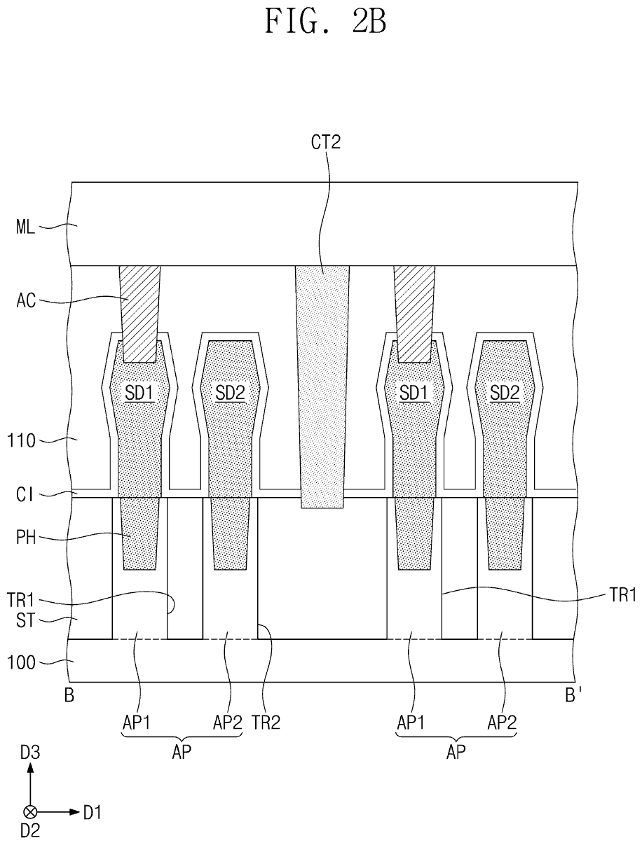

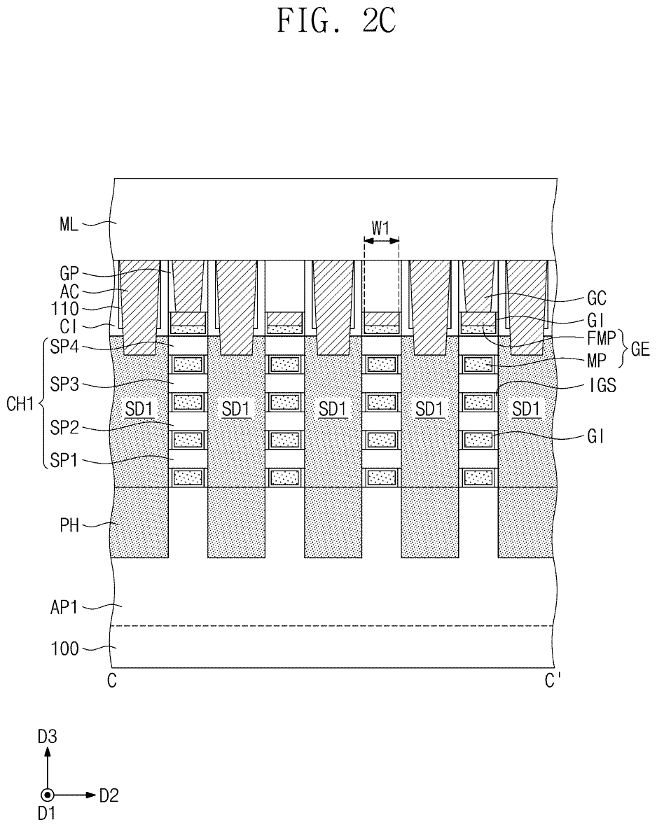

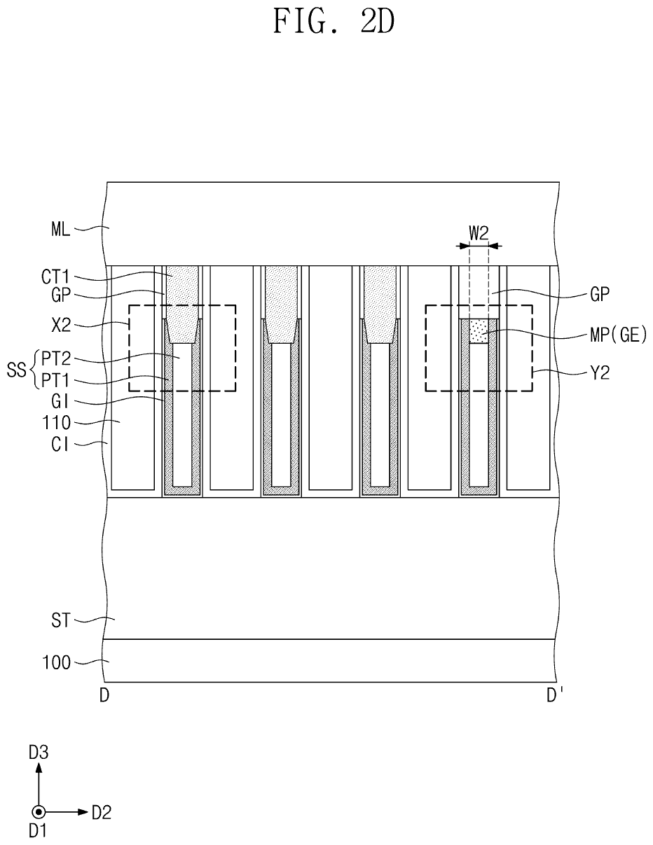

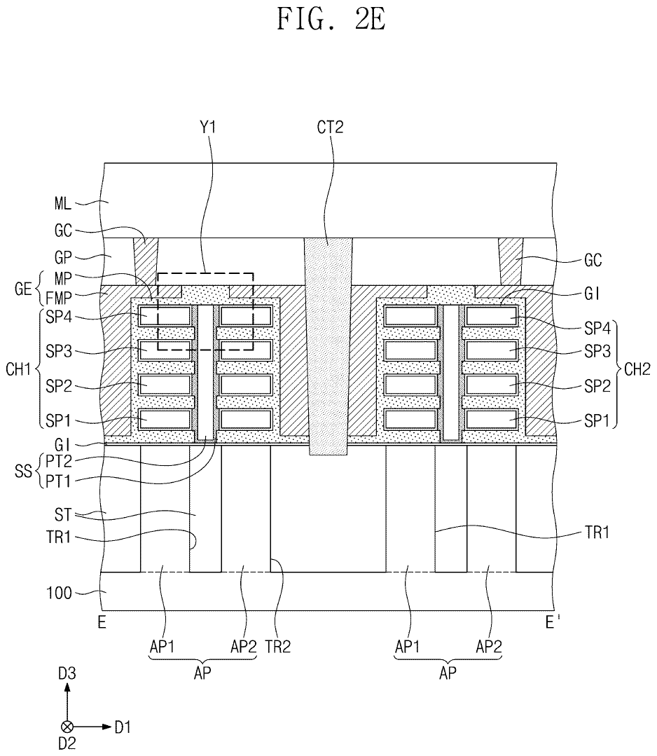

FIG. 1 is a plan view illustrating an example of a semiconductor device according to some implementations. FIGS. 2A to 2E are cross-sectional views taken along line A-A′, line B-B′, line C-C′, line D-D′, and line E-E′ of FIG. 1 illustrating an example of a semiconductor device according to some implementations.

In FIGS. 1 and 2A to 2E, a semiconductor device may include a substrate 100. A plurality of logic transistors constituting a logic circuit may be disposed on the substrate 100. For example, the substrate 100 may be a substrate including a silicon-based insulating layer. More specifically, the substrate 100 may include at least one of silicon oxide, silicon nitride, and silicon oxynitride. In the present disclosure, each of phrases such as “A or B”, “at least one of A and B”, “at least one of A or B”, “A, B, or C”, “at least one of A, B, and C”, and “at least one A, B, or C” may include any one of the items listed together in the corresponding phrase or all possible combinations thereof.

The substrate 100 may have a shape of a plate extending along a plane defined by a first direction D1 and a second direction D2. The upper surface of the substrate 100 may be parallel to the first direction D1 and the second direction D2. A third direction D3 may be orthogonal to the upper surface of the substrate 100. For example, the first direction D1, the second direction D2, and the third direction D3 may be orthogonal to each other. In this specification, the first direction D1 and the second direction D2 may be referred to as a horizontal direction. The third direction D3 may be referred to as a vertical direction.

Active patterns AP may be provided on the substrate 100. Each of the active patterns AP may include a first active pattern AP1 and a second active pattern AP2. The active patterns AP may be defined by first and second trenches TR1 and TR2 in the substrate 100. For example, the first active pattern AP1 and the second active pattern AP2 of each of the active patterns AP adjacent to each other in the first direction D1 may be defined by the first trench TR1. Active patterns AP adjacent to each other in the first direction D1 may be defined by the second trench TR2.

Each of the first active pattern AP1 and the second active pattern AP2 of the active patterns AP may extend in the second direction D2. The first active pattern AP1 and the second active pattern AP2 of the active patterns AP may be a portion of the substrate 100. For example, the first active pattern AP1 and the second active pattern AP2 of the active patterns AP may be a portion of the substrate 100 protruding in the third direction D3 perpendicular to the upper surface of the substrate 100. However, for convenience of explanation, the substrate 100 and the first active pattern AP1 and second active pattern AP2 are implemented to have different configurations.

A device isolation pattern ST may be provided on the substrate 100. The device isolation pattern ST may fill the first and second trenches TR1 and TR2. The active patterns AP and the first active pattern AP1 and the second active pattern AP2 of the active patterns AP may be spaced apart from each other in the first direction D1. In a plan view, the device isolation pattern ST may surround the first and second active patterns AP1 and AP2 of the active patterns AP. An upper surface of the device isolation pattern ST may be coplanar with upper surfaces of the first and second active patterns AP1 and AP2 of the active patterns AP, but is not limited thereto. For example, the device isolation pattern ST may include an insulating material, such as silicon oxide.

A first channel pattern CH1 and a second channel pattern CH2 may be provided on the first and second active patterns AP1 and AP2 of the active patterns AP, respectively. The first channel pattern CH1 and the second channel pattern CH2 may be adjacent to each other in the first direction D1. The first channel pattern CH1 and the second channel pattern CH2 adjacent to each other in the first direction D1 may be spaced apart from each other in the first direction D1 with a separation structure SS to be described later interposed therebetween. Each of the first channel pattern CH1 and the second channel pattern CH2 may be provided in a plural and may be spaced apart from each other in the second direction D2.

Each of the first and second channel patterns CH1, CH2 may include a first semiconductor pattern SP1, a second semiconductor pattern SP2, a third semiconductor pattern SP3, and a fourth semiconductor pattern SP4. The first to fourth semiconductor patterns SP1, SP2, SP3, and SP4 may be spaced apart from each other in a vertical direction (e.g., the third direction D3). For example, the first to fourth semiconductor patterns SP1, SP2, SP3, and SP4 may comprise crystalline silicon. According to some implementations, each of the first to fourth semiconductor patterns SP1, SP2, SP3, and SP4 may be a nanosheet.

First source/drain patterns SD1 and second source/drain pattern SD2 may be provided on the first and second active patterns AP1 and AP2 of the active patterns AP, respectively. The first source/drain patterns SD1 may be located on both sides of the first channel pattern CH1, and electrically connected with the first channel pattern CH1. The second source/drain patterns SD2 may be located on both sides of the second channel pattern CH2, and electrically connected with the second channel pattern CH2. For example, each of the first source/drain patterns SD1 may be located between a plurality of first channel patterns CH1, and each of the second source/drain pattern SD2 may be located between a plurality of second channel patterns CH2. For example, the first and second source/drain patterns SD1 and SD2 may include at least one of silicon and silicon-germanium.

The first and second source/drain patterns SD1 and SD2 may include impurity regions having a first conductivity type (e.g., p-type) or a second conductivity type (e.g., n-type). According to some implementations, the first and second source/drain patterns SD1 and SD2 may include impurity regions having a same conductivity type. According to some implementations, the first and second source/drain patterns SD1 and SD2 may include impurity regions having different conductivity types.

Separation structures SS may be provided on the substrate 100. Each of the separation structures SS may be located between the first channel pattern CH1 and the second channel pattern CH2 adjacent to each other in the first direction D1. In a plan view, the separation structures SS may be spaced apart from each other in the first direction D1 and the second direction D2, and may be two-dimensionally arranged. In addition, each of the separation structures SS may have a shape of a pillar extending in the third direction D3. Accordingly, the first channel pattern CH1 and the second channel pattern CH2 adjacent to each other in the first direction D1 may be spaced apart from each other. Each of the separation structures SS may overlap with the device isolation pattern ST in the first trench TR1. For example, the separation structures SS may include an insulating material such as silicon oxide, silicon nitride, silicon oxynitride, and silicon oxycarbide (SiOC), but is not limited there to.

Each of the separating structures SS may comprise a first pattern PT1 and a second pattern PT2. The first pattern PT1 may be adjacent to the first channel pattern CH1 and the second channel pattern CH2. The second pattern PT2 may be located on the inner side of the first pattern PT1. For example, the first pattern PT1 may be located between the second pattern PT2 and the first channel pattern CH1 and between the second patterns PT2 and the second channel pattern CH2. That is, the first pattern PT1 may extend between the second pattern PT2 and the first and second channel patterns CH1 and CH2. The second pattern PT2 may be spaced apart from the first and second channel patterns CH1 and CH2. According to some implementations, the first pattern PT1 may have a cylindrical shape with an inner surface, and the second pattern PT2 may have a columnar shape filling the inner surface of the first pattern PT1.

Gate electrodes GE may be provided on the first channel pattern CH1, the second channel pattern CH2 and the separation structures SS. Each of the gate electrodes GE may extend in the first direction D1 and be spaced apart in the second direction D2. The gate electrodes GE may surround three surfaces of each of the first to fourth semiconductor patterns SP1, SP2, SP3, and SP4 of each of the second and first channel patterns CH1 and CH2. For example, the gate electrodes GE may be located on an upper surface, a lower surface, and a side surface of each of the first to fourth semiconductor patterns SP1, SP2, SP3, and SP4. Each of the gate electrodes GE may be spaced apart in the first direction D1 by a first gate cutting pattern CT1 on the separation structures SS and/or a second gate cutting pattern CT2 between the active patterns AP.

Each of the gate electrodes GE may include a metal pattern MP and a filling metal pattern FMP on the metal pattern MP. The metal pattern MP may fill between the first to fourth semiconductor patterns SP1, SP2, SP3, and SP4 of each of the first and second channel patterns CH1 and CH2. The filling metal pattern FMP may cover the metal pattern MP. For example, the filling metal pattern FMP may not be provided between the first to fourth semiconductor patterns SP1, SP2, SP3, and SP4 of each of the first and second channel patterns CH1 and CH2. The filling metal pattern FMP may be spaced apart from the first to fourth semiconductor patterns SP1, SP2, SP3, and SP4 of each of the first and second channel patterns CH1 and CH2 by the metal pattern MP therebetween.

A portion of the gate electrodes GE that overlaps the first and second channel patterns CH1 and CH2 may have a first width W1 in the second direction D2. A gate insulating layer GI may be positioned on both sides of the portion of the gate electrodes GE. When the first gate cutting patterns CT1 may be not provided, another portion of the gate electrodes GE that overlaps the separation structures SS may have a second width W2 in the second direction D2. The first pattern PT1 and the gate insulating layer GI may be located on both sides of another portion of the gate electrodes GE. According to the first pattern PT1, a first width W1 of a portion of the gate electrodes GE may be greater than a second width W2 of another portion of the gate electrode GE. For example, the gate electrodes GE may have different widths along the horizontal direction.

According to some implementations, the metal pattern MP may include a work function metal that adjusts the threshold voltage of the transistor. The composition in the work function metal may be adjusted to achieve a target threshold voltage of the transistor. For example, the metal pattern MP may include a titanium nitride TiN, a tantalum nitride TaN, a titanium oxynitride TiON, a titanium silicon nitride TiSiN, a titanium aluminum nitride TiAlN, a tungsten carbon nitride WCN, or a molybdenum nitride MoN. In some implementations, the metal pattern MP may include a metal oxynitride, a metal oxycarbide or a metal oxynitride carbide. The filling metal pattern FMP may include a material having a lower contact resistance compared to the metal pattern MP. For example, the filling metal pattern FMP may include low-resistance metal, for example, at least one of aluminum (Al), tungsten (W), titanium (Ti) and tantalum (Ta).

Inner gate spacers IGS may be provided between the metal pattern MP of the gate electrodes GE and the first source/drain patterns SD1 and between the metal pattern MP of the gate electrode GE and the second source/drain pattern SD2. For example, the inner gate spacers IGS may not be provided between the first and second channel patterns CH1 and CH2 and the separation structures SS. According to some implementations, the inner gate spacers (IGS) may be omitted.

The gate insulating layer GI may be provided between the gate electrodes GE and the first to fourth semiconductor patterns SP1, SP2, SP3, and SP4 of the first and second channel patterns CH1 and CH2. The gate insulating layer GI may surround four surfaces of each of the first to fourth semiconductor patterns SP1, SP2, SP3, and SP4. For example, the gate insulating layer GI may cover the upper surface, the lower surface, and the side surfaces of each of the first to fourth semiconductor patterns SP1, SP2, SP3, and SP4. For example, the gate insulating layer GI may include silicon oxide, silicon oxynitride, and/or a high dielectric constant material. Herein, the high-k material may be a material having a higher dielectric constant than silicon oxide.

The gate insulating layer GI may be in contact with each of the separation structures SS. For example, the gate insulating layer GI may be provided on the lower surface of each of the separation structures SS. The gate insulating layer GI may extend between the separation structures SS and a capping insulating layer CI described later. The gate insulating layer GI may partially cover the outer surface of the first pattern PT1. The gate insulating layer GI may extend from regions between the lower surface of the separation structures SS and the device isolation pattern ST, to regions between the gate electrodes GE and the active patterns AP.

Gate capping patterns GP may be provided on the gate electrodes GE. Each of the gate capping patterns GP may extend along the gate electrodes GE in the first direction D1 and may be spaced apart each other in the second direction D2. The gate capping patterns GP may cover the upper surface of each of the gate electrodes GE. For example, the gate capping patterns GP may include at least one of SiON, SiCN, SiOCN, and SiN.

Upper insulating patterns 110 may be provided on the substrate 100. The upper insulation patterns 110 may cover the first and second source/drain patterns SD1 and SD2. In addition, the upper insulation patterns 110 may be located between the separation structures SS. Upper surfaces of the upper insulating patterns 110 may be substantially coplanar with the upper surfaces of the gate capping patterns GP. For example, the upper insulating patterns 110 may include an insulating material such as silicon oxide.

The capping insulating layer CI may be provided between the upper insulating patterns 110 and the first and second source/drain patterns SD1 and SD2. The capping insulating layer CI may extend on the device isolation pattern ST, and may cover the first and second source/drain patterns SD1 and SD2. In addition, the capping insulating layer CI may extend between the upper insulating patterns 110 and the separation structures SS. For example, the capping insulating layer CI may include an insulating material different from the upper insulating patterns 110. According to some implementations, the capping insulating layer CI may include a single layer or a multilayer of different insulating materials.

The first gate cutting patterns CT1 may be provided on the separation structures SS. Each of the first gate cutting patterns CT1 may overlap each of the separation structures SS. The first gate cutting patterns CT1 may penetrate a portion of the gate capping patterns GP and a portion of the gate electrodes GE to contact the separation structures SS. The gate electrodes GE corresponding to each of the first and second channel patterns CH1 and CH2 may be spaced apart from each other in the first direction D1 by the first gate cutting patterns CT1. In a plan view, each of the first gate cutting patterns CT1 may have a circular or elliptical shape. Accordingly, the first gate cutting patterns CT1 may be formed easily with a small size. For example, the first gate cutting patterns CT1 may not be provided on some of the separation structures SS. That is, one of the first gate cutting patterns CT1 may be provided on at least one of the separation structures SS.

When the first gate cutting patterns CT1 are not provided, the gate electrodes GE may not be spaced apart in the first direction D1 by the first gate cutting pattern CT1. The gate electrodes GE may cover the separation structures SS. The first and second channel patterns CH1 and CH2 and the gate electrodes GE adjacent in the first direction D1 may be parts of a single transistor. Accordingly, a transistor with a relatively long channel length may be formed.

A second gate cutting pattern CT2 may be provided on the substrate 100. The second gate cutting pattern CT2 may extend in the second direction D2 between the first gate cutting patterns CT1. The second gate cutting pattern CT2 may be horizontally spaced apart from the first gate cutting patterns CT1 and the separation structures SS. In a plan view, the second gate cutting pattern CT2 may have the shape of a line or a bar. The second gate cutting pattern CT2 may penetrate the gate capping patterns GP and the gate electrodes GE. The second gate cutting pattern CT2 may extend on a top of the device isolation pattern ST. The gate electrodes GE on the different active patterns AP may be spaced apart from each other in the first direction D1 with to the second gate cutting pattern CT2 therebetween. For example, a vertical length of the second gate cutting pattern CT2 in the third direction D3 may be greater than a vertical length of each of the first gate cutting patterns CT1 in the third direction D3.

According to some implementations, the first and second gate cutting patterns CT1 and CT2 may include at least one of SiON, SiCN, SiOCN, and SiN, the same as the gate capping patterns GP. In this case, the interface between the first and second gate cutting patterns CT1 and CT2 and the gate capping patterns GP may not be visible. In some implementations, the first and second gate cutting patterns CT1 and CT2 may include at least one of SiON, SiCN, SiOCN and SiN different from the gate capping patterns GP. In this case, the interface between the first and second gate cutting patterns CT1 and CT2 and the gate capping patterns GP is visible.

Active contacts AC may be provided in the upper insulation patterns 110. The active contacts AC may penetrate the upper insulating patterns 110 and extend to the corresponding first and second source/drain patterns SD1 and SD2. The active contacts AC may be electrically connected with corresponding first and second source/drain patterns SD1 and SD2. For example, the active contacts AC may include at least one of a metal material (e.g., Ti, Mo, W, Cu, Al, Ta, Ru, Ir, Co, etc.) and a metal nitride (e.g., a nitride of Ti, Mo, W, Cu, Al. Ta, Ru, Ir, Co, or etc.).

Gate contacts GC may be provided in the gate capping patterns GP. The gate contacts GC may penetrate the gate capping patterns GP and be electrically connected to corresponding gate electrodes GE. For example, the gate contacts GC may include at least one of a metal material (e.g., Ti, Mo, W, Cu, Al, Ta, Ru, Ir, Co, or etc.) and a metal nitride (e.g., a nitride of Ti, Mo, W, Cu, Al. Ta, Ru, Ir, Co, or etc.).

A metal layer ML may be provided on the upper insulation patterns 110. The metal layer ML may include a wiring structure therein. The wiring structure of the metal layer ML may be connected with the active contacts AC and the gate contacts GC. For example, the metal layer ML may be electrically connected with the first and second source/drain patterns SD1 and SD2 and the gate electrodes GE through the active contacts AC and the gate contacts GC. Adjacent transistors may transmit and receive electrical signals to and from each other through the metal layer ML. According to some implementations, a plurality of metal layers ML may be provided and stacked in the third direction D3.

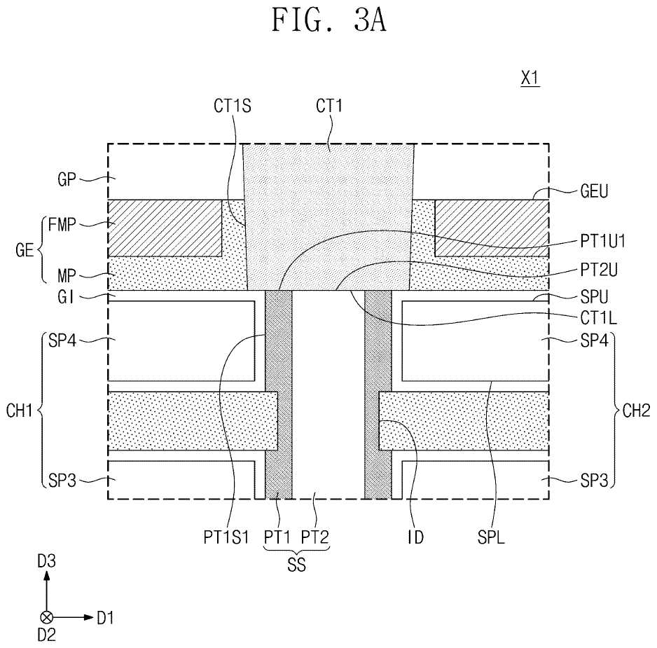

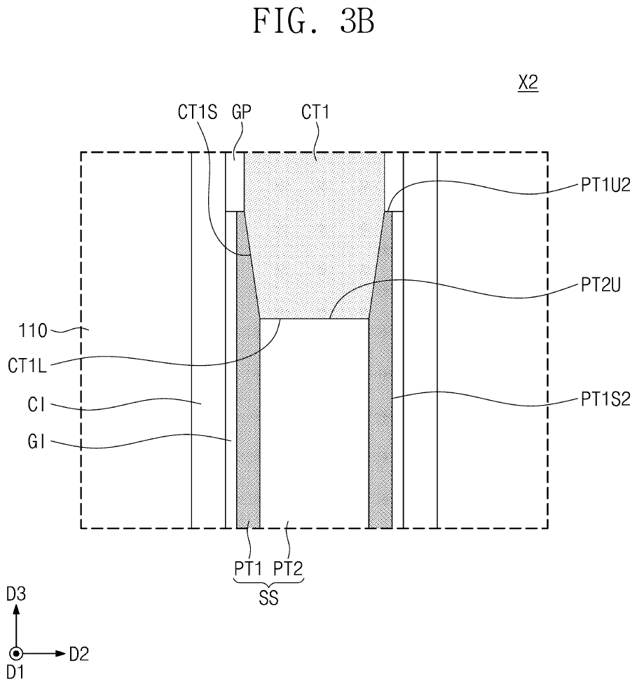

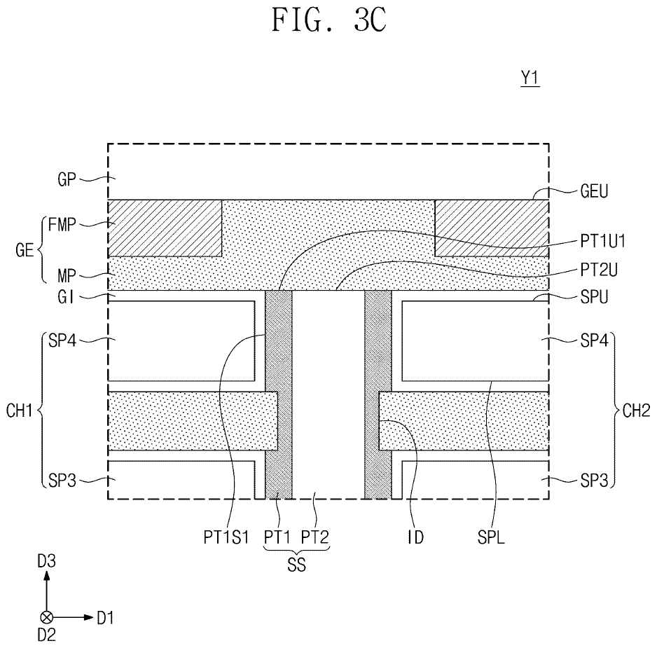

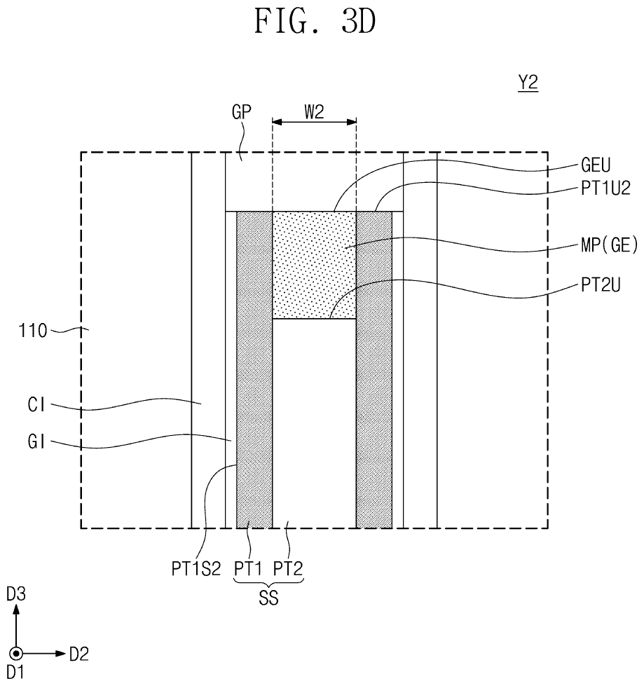

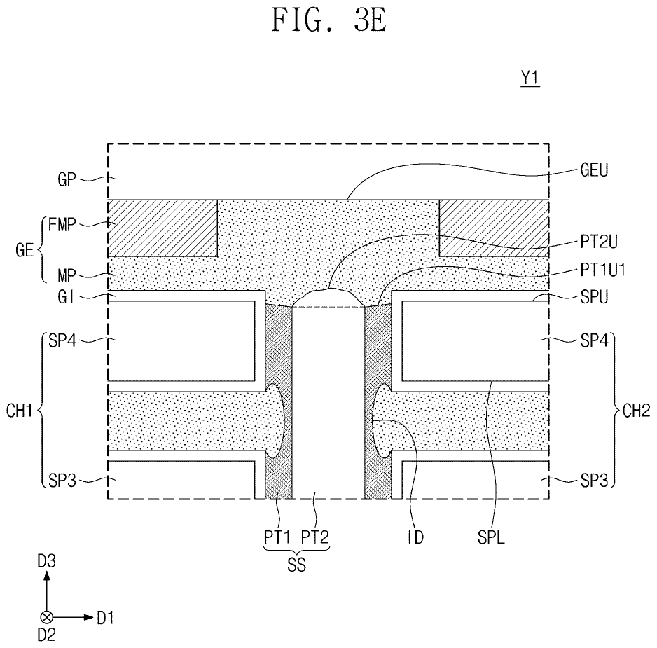

FIGS. 3A to 3E are enlarged views for illustrating an example of a portion of a semiconductor device according to some implementations. FIG. 3A is an enlarged view of an X1 region in FIG. 2A. FIG. 3B is an enlarged view of the X2 region in FIG. 2D. FIG. 3C is an enlarged view of the Y1 region in FIG. 2E. FIG. 3D is an enlarged view of the Y2 region in FIG. 2D. FIG. 3E is an enlarged view of the Y1 region in FIG. 2E.

In FIGS. 3A to 3D, the first pattern PT1 of the separation structure SS may have first side surfaces PT1S1 perpendicular to the first direction D1 and second side surfaces PT1S2 perpendicular to the second direction D2. For example, the first side surfaces PT1S1 of the first pattern PT1 may be adjacent to the first and second channel patterns CH1 and CH2. The second side surfaces PT1S2 of the first pattern PT1 may be adjacent to the capping insulating layer CI and the upper insulating patterns 110. The second sides PT1S2 of the first pattern PT1 may extend further in the third direction D3 than the first sides PT1S1.

The first pattern PT1 of the separating structure SS may have a first upper surface PT1U1 and a second upper surface PT1U2 located at a higher level than the first upper surface PT1U1. In other words, the first pattern PT1 may have upper surfaces of different levels. In this specification, the level may mean a height (or a length) in the third direction D3 from the upper surface of the substrate 100 of FIG. 2A or a lower surface of the substrate 10. For example, the second upper surface PT1U2 of the first pattern PT1 may correspond to the uppermost surface of the first patterns PT1.

The first upper surface PT1U1 of the first pattern PT1 may be located at the same level as the upper surface PT2U of the second pattern PT2 and a lower surface CT1L of the first gate cutting pattern CT1. The second upper surface PT1U2 of the first pattern PT1 may be located at a higher level than the upper surface PT2U of the second pattern PT2 and the lower surface CT1L of the first gate cutting pattern CT1. The second upper surface PT1U2 of the first pattern PT1 may be coplanar with the upper surface GEU of the gate electrodes GE. The second upper surface PT1U2 of the first pattern PT1 may be in contact with the gate capping patterns GP.

A portion of the first pattern PT1 may extend further onto the second pattern PT2. Thus, a portion of the upper surface of the first pattern PT1 may be located at a higher level than the upper surface PT2U of the second pattern PT2.

The upper surface PT2U of the second pattern PT2 of the separating structure SS may be located at a higher level than a lower surface SPL of the fourth semiconductor pattern SP4 of each of the first and second channel patterns CH1 and CH2. For example, the upper surface PT2U of the second pattern PT2 may be located between the lower surface SPL and the upper surface SPU of the fourth semiconductor pattern SP4. In some implementations, the upper surface PT2U of the second pattern PT2 may be substantially coplanar with the upper surface SPU of the fourth semiconductor pattern SP4. In some implementations, the upper surface PT2U of the second pattern PT2 may be located at a higher level than the upper surface SPU of the fourth semiconductor pattern SP4. That is, the first upper surface PT1U1 of the first pattern PT1 and the upper surface PT2U of the second pattern PT2 may be located at a higher level than the lower surface SPL of the uppermost semiconductor pattern of the plurality of semiconductor patterns of each of the first and second channel patterns CH1 and CH2.

The gate insulating layer GI may be located between the third and fourth semiconductor patterns SP3 and SP4 of the first and second channel patterns CH1 and CH2 and the first pattern PT1 of the separation structure SS, and between the capping insulating layer CI and the first patterns PT1 of the separation structure SS. For example, the gate insulating layer GI may be partially in contact with the first side surfaces PT1S1 of the first pattern PT1, and surround each of the first to fourth semiconductor patterns SP1, SP2, SP3, and SP4 of the first and second channel patterns CH1 and CH2 of FIG. 2A. The gate insulating layer GI may not extend into indented regions ID of the first pattern PT1 described later. In addition, the gate insulating layer GI may extend in the third direction D3 between the capping insulating layer CI and the first pattern PT1. The gate insulating layer GI may be in contact with the second side surfaces PT1S2 of the first pattern PT1. The gate insulating layer GI may be aligned with the second upper surface PT1U2 of the first pattern PT1. Accordingly, the gate insulating layer GI may be in contact with at least a portion of the side surface of the first pattern PT1.

The first pattern PT1 of the separating structure SS may have the indented regions ID at its first side surfaces PT1S1. For example, the indented regions ID may be areas recessed towards the second pattern PT2 at the first side surfaces PT1S1 of the first pattern PT1. Thus, the first side surfaces PT1S1 of the first pattern PT1 may have grooves. In some implementations, the first pattern PT1 may have no indented regions ID at its second side surfaces PT1S2. The second side surfaces PT1S2 of the first pattern PT1 may not have grooves and have a constant slope.

The indented regions ID of the first pattern PT1 may be located between the third and fourth semiconductor patterns SP3 and SP4 of the first and second channel patterns CH1 and CH2. The indented regions ID may be spaced apart from the third and fourth semiconductor patterns SP3 and SP4 in the third direction D3. In other words, the indented regions ID may be vertically spaced apart from the first to fourth semiconductor patterns SP1, SP2, SP3, and SP4 of the first and second channel patterns CH1 and CH2 of FIG. 2A. According to the indented regions ID of the first pattern PT1, the metal pattern MP of each of the gate electrodes GE may be closer to the separation structure SS than the third and fourth semiconductor patterns SP3 and SP4 of the first and second channel patterns CH1 and CH2. For example, the metal pattern MP of each of the gate electrodes GE may be adjacent to the second pattern PT2 of the separation structure SS than the first to fourth semiconductor patterns SP1, SP2, SP3, and SP4 of the first and second channel patterns CH1 and CH2 of FIG. 2A. According to this, the length of the gate electrodes GE overlapping with the first and second channel patterns CH1 and CH2 may be increased. Accordingly, a gate controllability of the gate electrodes GE may be improved.

The first gate cutting pattern CT1 may be located on the separation structure SS and be in contact with the separation structure SS. The lower surface CT1L of the first gate cutting pattern CT1 may be in contact with the first upper surface PT1U1 of the first pattern PT1 and the upper surface PT2U of the second pattern PT2. The lower side surface CT1S of the first gate cutting pattern CT1 may be in contact with the metal pattern MP of each of the gate electrodes GE and the first pattern PT1 of the separation structure SS. For example, the first side surfaces PT1S1 of the first pattern PT1 may not extend on the lower side surface CT1S of the first gate cutting pattern CT1, but the second side surfaces PT1S2 of the first patterns PT1 may extend further onto the lower side surface CT1S of first gate cutting patterns CT1. That is, a portion of the first pattern PT1 may partially cover the lower side surface CT1S of the first gate cutting pattern CT1.

Herein, the first gate cutting pattern CT1 may be a structure for electrically isolating adjacent gate electrodes GE. When the first gate cutting pattern CT1 may be provided, the gate electrode GE on the first channel pattern CH1 and the gate electrode GE on the second channel pattern CH2 may be spaced apart from each other in the first direction D1 to operate as independent transistors. When the first gate cutting pattern CT1 may not be provided, the gate electrode GE on the first channel pattern CH1 and the gate electrode GE on the second channel pattern CH2 may be connected to operate as one transistor. Thus, transistors having different channel lengths in one logic cell may be formed together.

The first pattern PT1 of the separation structure SS may prevent a portion of the gate electrodes GE from remaining on the lower side surface CT1S of the first gate cutting pattern CT1. Thus, the gate electrode GE on the first channel pattern CH1 and the gate electrode GE on the second channel pattern CH2 may be electrically separated from each other. More specifically, to prevent parasitic capacitors due to remaining portions of the gate electrodes GE, the separation structures SS may be formed prior to the formation of the gate electrodes GE. A portion of the gate electrodes GE that overlaps the separating structure SS by the first pattern PT1 having different levels of upper surfaces may be located in the first patternPT1.

A portion of the gate electrodes GE located between the second side surfaces PT1S2 of the first pattern PT1 may have a relatively small second width W2 according to the first pattern PT1. Thus, a size of the first gate cutting pattern CT1 required to separate the gate electrodes GE in the first direction D1 may be reduced. Furthermore, the first gate cutting pattern CT1 may be formed in a self-aligned manner by the second side surfaces PT1S2 of the first pattern PT1. As a result, the first gate cutting pattern CT1 may be easily formed with a small size, and a semiconductor device with improved electrical characteristics and integration may be provided.

In FIG. 3E, the first pattern PT1 of the separation structure SS may have indented regions ID recessed from its first side surfaces PT1S1. Each of the indented regions ID of the first partial pattern PT1 may be recessed from the first side surfaces PT1S1 of the first patterns PT1 towards the second pattern PT2. According to some implementations, each of the indented regions ID of the first pattern PT1 may be further recessed in the third direction D3. Each of the indented regions ID of the first pattern PT1 may be an area recessed in the first direction D1 and the third direction D3. In this case, the inner surface of each of the indent regions ID may be a curved surface, but is not limited thereto.

According to some implementations, the second pattern PT2 of the separating structure SS may further comprise a protrusion portion on top thereof. For example, the protrusion portion of the second pattern PT2 may extend into the metal pattern MP of the gate electrodes GE. In this case, the second pattern PT2 may have an upper surface PT2U that is not parallel to the first direction D1 and the second direction D2. For example, the upper surface PT2U of the second pattern PT2 may be an uneven surface whose slope is not constant. Therefore, the first upper surface PT1U1 of the first pattern PT1 and the upper surface PT2U of the second pattern PT2 may not be coplanar. The upper surface PT2U of the second pattern PT2 may be located at a higher level than the first upper surface PT1U1 of the first pattern PT1.

When the first gate cutting pattern CT1 may be provided on the separation structure SS, the protrusion portion of the second pattern PT2 may not be visible. In other words, the protrusion portion of the second pattern PT2 of the separation structure SS may be visible when the first gate cutting pattern CT1 may not be provided.

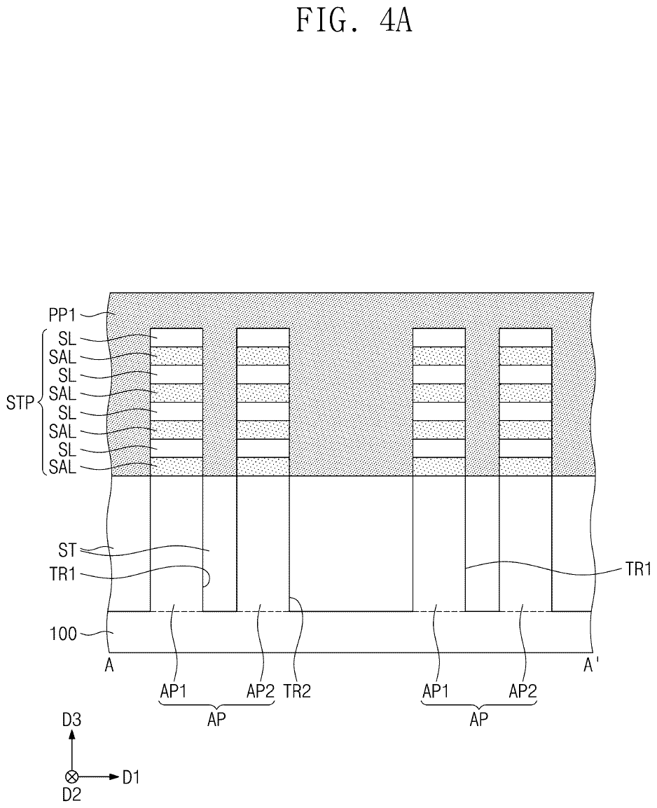

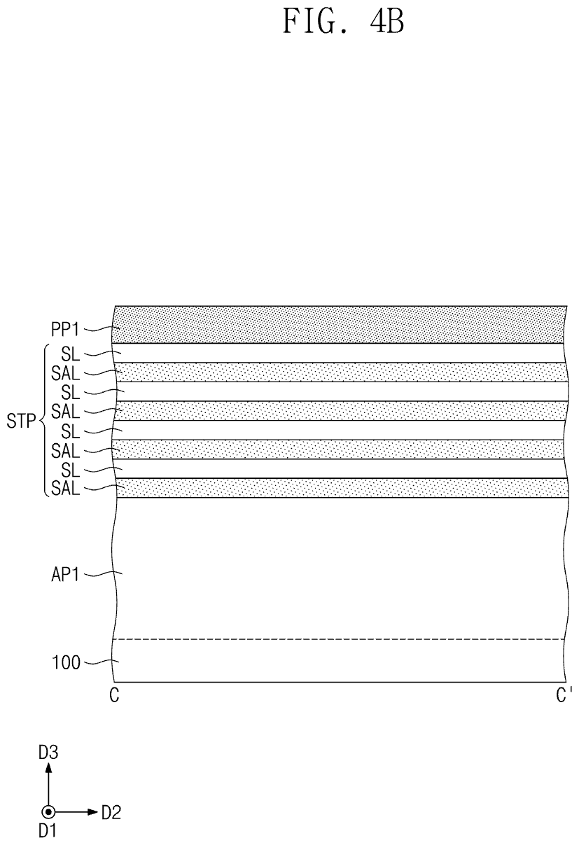

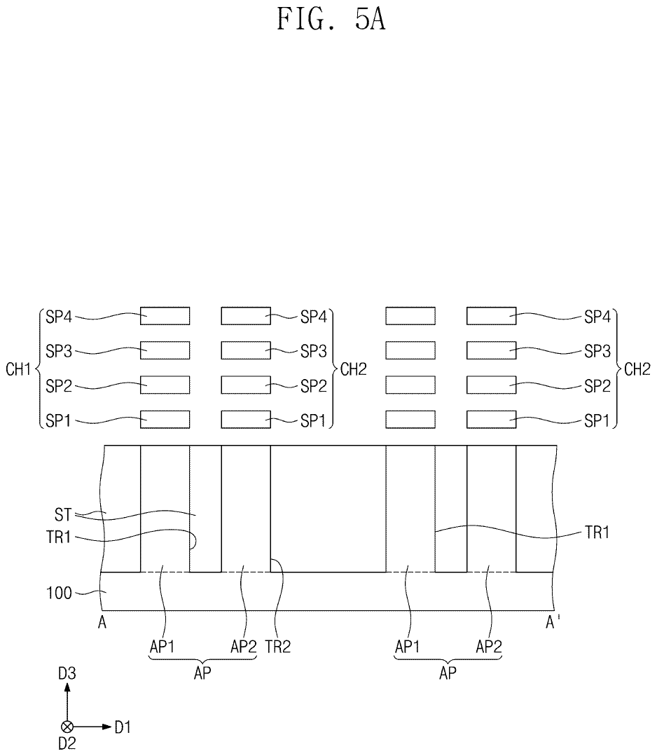

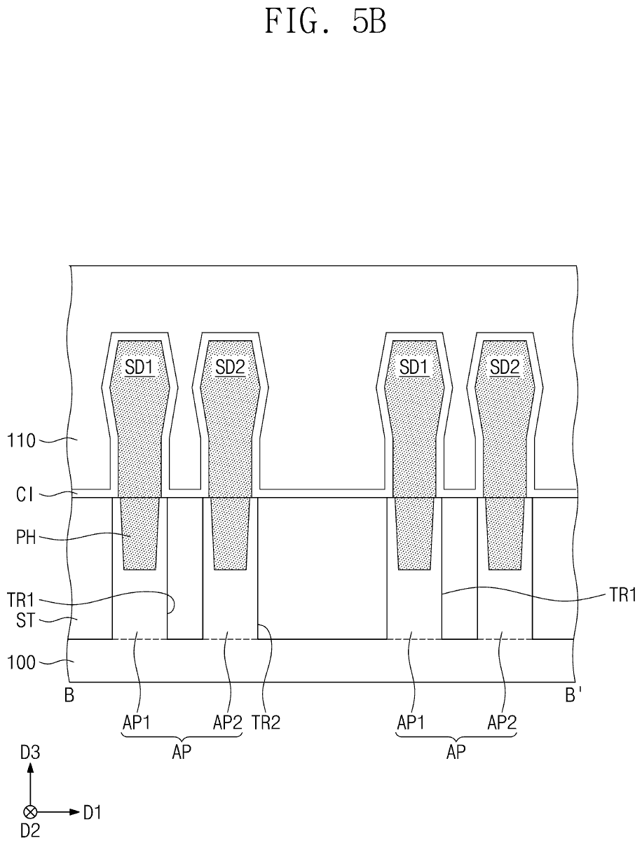

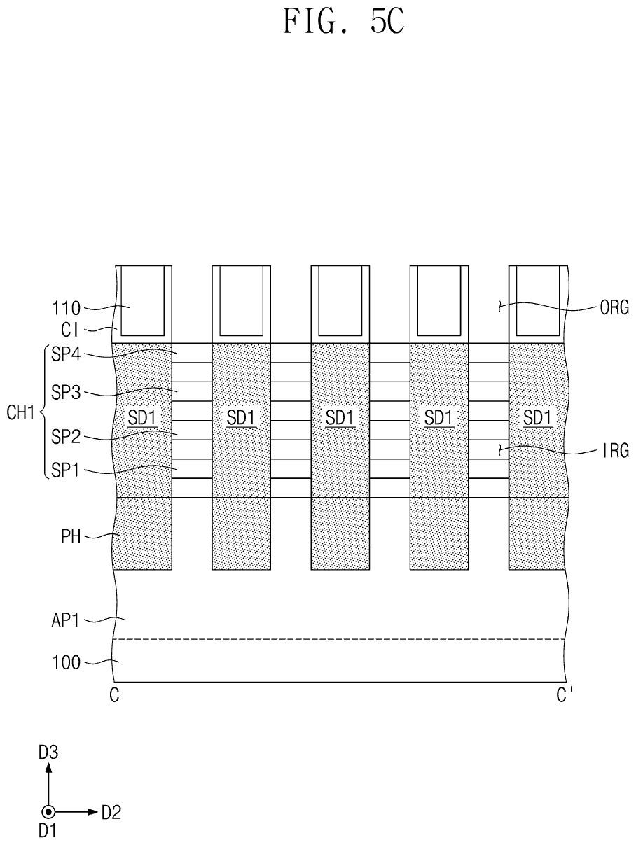

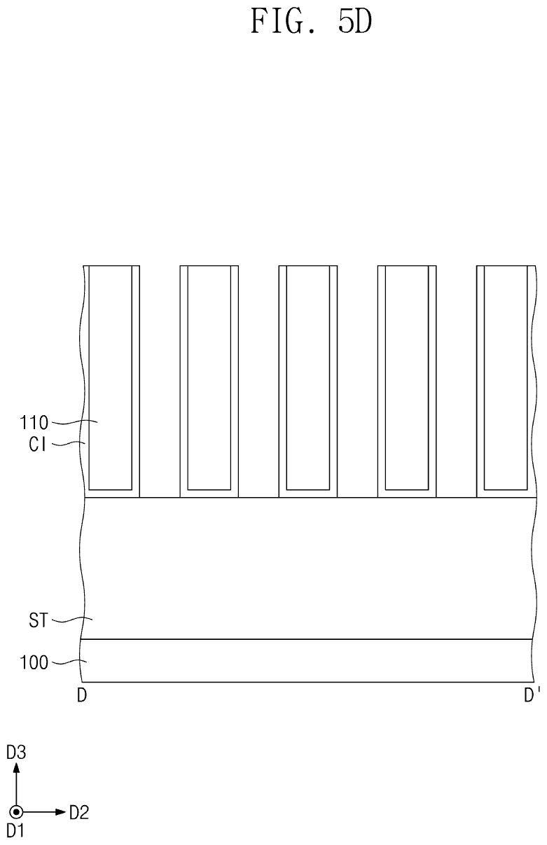

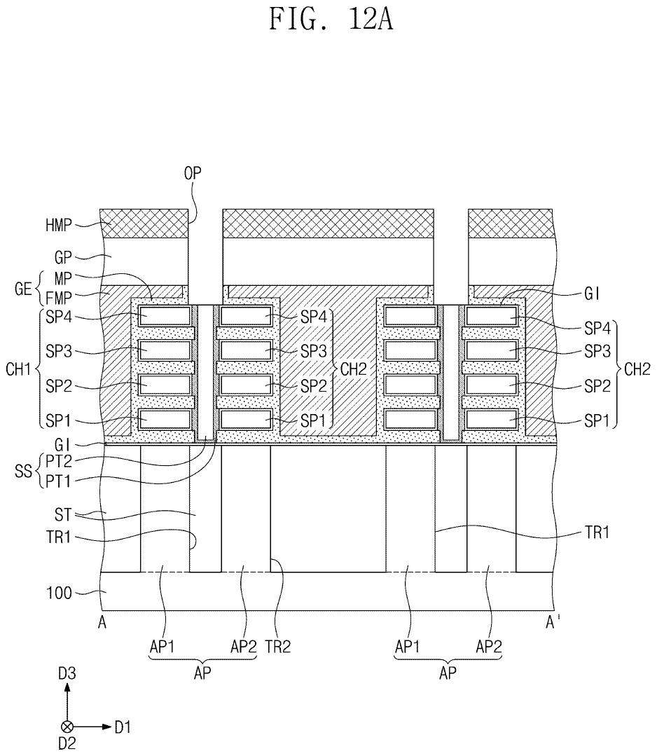

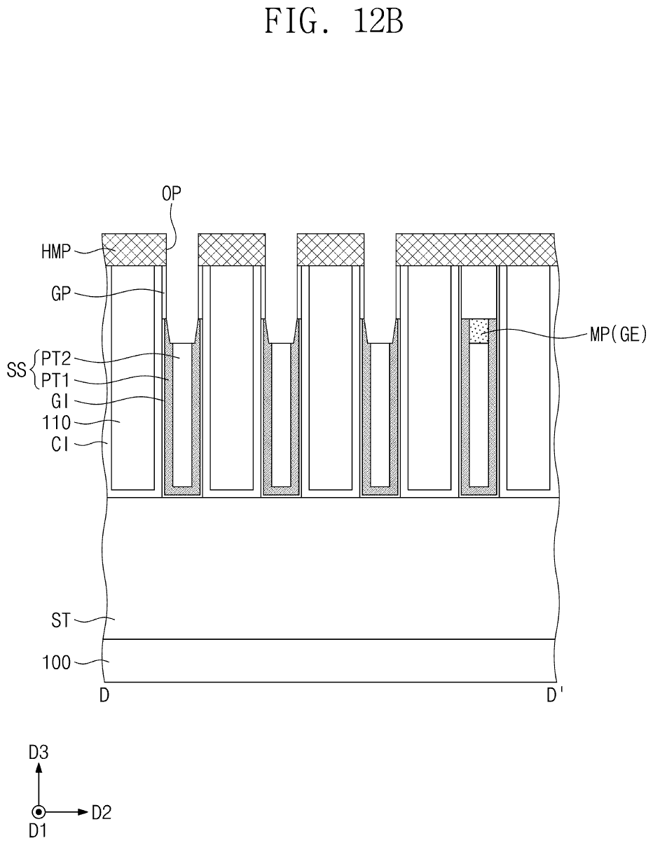

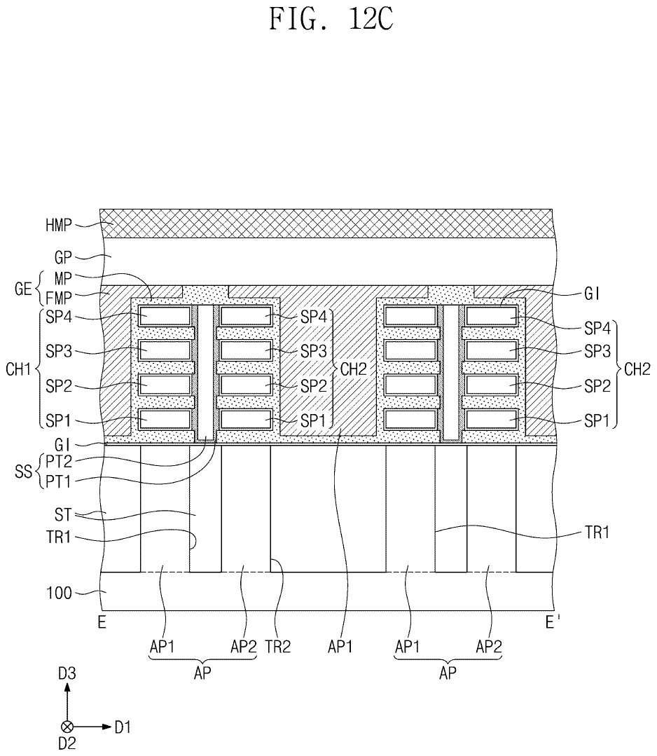

FIGS. 4A to 12C are diagrams illustrating an example of a method of manufacturing a semiconductor device according to some implementations. FIGS. 4A, 5A, 6A, 7A, 8A, 9A, 10A, 11A, and 12A are cross-sectional views taken along line A-A′ of FIG. 1. FIG. 5B is a cross-sectional view taken along line B-B′ in FIG. 1. FIGS. 4B, 5C, 6B, 7B, 8B, 9B, 10B, and 11B are cross-sectional views taken along line C-C′ of FIG. 1. FIGS. 5D, 6C, 7C, 8C, 9C, 10C, 11C, and 12B are cross-sectional views taken along line D-D′ of FIG. 1. FIG. 12C is a cross-sectional view taken along line E-E′ in FIG. 1.

In FIGS. 4A and 4B, a substrate 100 may be provided. The upper surface of the substrate 100 may be parallel to the first direction D1 and the second direction D2 crossing with each other. The upper surface of the substrate 100 may be perpendicular to the third direction D3. For example, the first direction D1, the second direction D2, and the third direction D3 may be orthogonal to each other. The substrate 100 may be a substrate including silicon, germanium, silicon-germanium, etc., or a compound semiconductor substrate, but not limited thereto.

Stacking patterns STP may be formed on the substrate 100. Forming the stacking patterns STP may include alternately forming semiconductor layers SL and sacrificial layers SAL on the substrate 100, and performing a patterning process. The patterning process may include removing a top portion of the substrate 100 together with the semiconductor layers SL and the sacrificial layers SAL. Thereby, the active patterns AP each including the first and second active patterns AP1 and AP2 and the first and second trenches TR1 and TR2 defining the active patterns AP may be formed. Each of the first and second active patterns AP1 and AP2 of the active patterns AP may extend in the second direction D2.

The stacking patterns STP may include the semiconductor layers SL and the sacrificial layers SAL alternately stacked in the third direction D3. The sacrificial layers SAL may include a material that may have an etch selectivity with the semiconductor layers SL. In the process of removing the sacrificial layers SAL described below, the semiconductor layers SL may not be removed or may be removed in small amounts. For example, the semiconductor layers SL may include one of silicon, germanium, and silicon-germanium, and the sacrificial layers SAL may include another one of silicon, the germanium, and the silicon-germanium.

The device isolation pattern ST may be formed in the first and second trenches TR1 and TR2. The device isolation pattern ST may fill each of the first and second trenches TR1 and TR2. Forming the device isolation pattern ST may include forming an insulating layer covering the first and second trenches TR1 and TR2 and the stacking patterns STP, and performing a planarization process on the insulating layer to expose the stacking pattern STP again.

Then, a first sacrificial pattern PP1 covering the stacked patterns STP and the device isolation pattern ST may be formed. An upper surface of the first sacrificial pattern PP1 may be located at a higher level than an upper surfaces of the stacking patterns STP. For example, the first sacrificial pattern PP1 may include amorphous silicon and/or poly silicon.

In FIGS. 5A, 5B, 5C, and 5D, a mask pattern may be formed on the first sacrificial pattern PP1, and an etching process using the mask pattern may be performed. The etching process may include removing a portion of the stacking patterns STP and a portion of the first and second active patterns AP1 and AP2.

Sacrificial contact patterns PH may be formed in the first and second active patterns AP1 and AP2. The sacrificial contact patterns PH may include a material having an etch selectivity with respect to the first and second active patterns AP1 and AP2. For example, the sacrificial contact patterns PH may be formed with an epitaxial growth process and include silicon-germanium.

First and second source/drain patterns SD1 and SD2 may be formed on each of the sacrificial contact patterns PH. The first and second source/drain patterns SD1 and SD2 may be formed in a Selective Epitaxial Growth (SEG) process using the sacrificial contact patterns PH as a seed layer. Each of the first and second source/drain patterns SD1 and SD2 may be located between stacked patterns STP.

During the first and second source/drain patterns SD1 and SD2 are being formed, dopants may be implanted in-situ into the first and second sources/drain patternsSD1 and SD2. However, the present disclosure is not limited thereto, and the dopants may be implanted after forming the first and second source/drain patterns SD1 and SD2.

Then, the capping insulating layer CI may be formed on the substrate 100. The capping insulating layer CI may cover the first and second source/drain patterns SD1 and SD2, the first sacrificial pattern PP1, and the device isolation pattern ST with a uniform thickness.

Upper insulation patterns 110 may be formed on the first and second source/drain patterns SD1 and SD2. The upper insulating patterns 110 may cover the capping insulating layer CI. Forming the upper insulation patterns 110 may include performing a planarization process on the upper insulation patterns 100. The planarization process may include exposing the first sacrificial pattern PP1 again.

The exposed first sacrificial pattern PP1 may be selectively removed. Removing the first sacrificial pattern PP1 may include a wet etch process with an etchant that selectively removes polysilicon. By removing the first sacrificial pattern PP1, an outer region ORG may be formed. Due to the outer region ORG, the stacking patterns STP may be exposed to the outside.

The sacrificial layers SAL of the stacking patterns STP exposed through the outer region ORG may be selectively removed. The sacrificial layers SAL may be selectively removed to form inner regions IRG. An etching process that selectively removes the sacrificial layers SAL may remove only the sacrificial layers SAL while leaving the semiconductor layers SL intact. The etching process to remove the sacrificial layers SAL may have a high etch rate for silicon-germanium. The remaining semiconductor layers SL may be formed of the first to fourth semiconductor patterns SP1, SP2, SP3, and SP4. Accordingly, the first and second channel patterns CH1 and CH2 each including the first to fourth semiconductor patterns SP1, SP2, SP3, and SP4 may be formed.

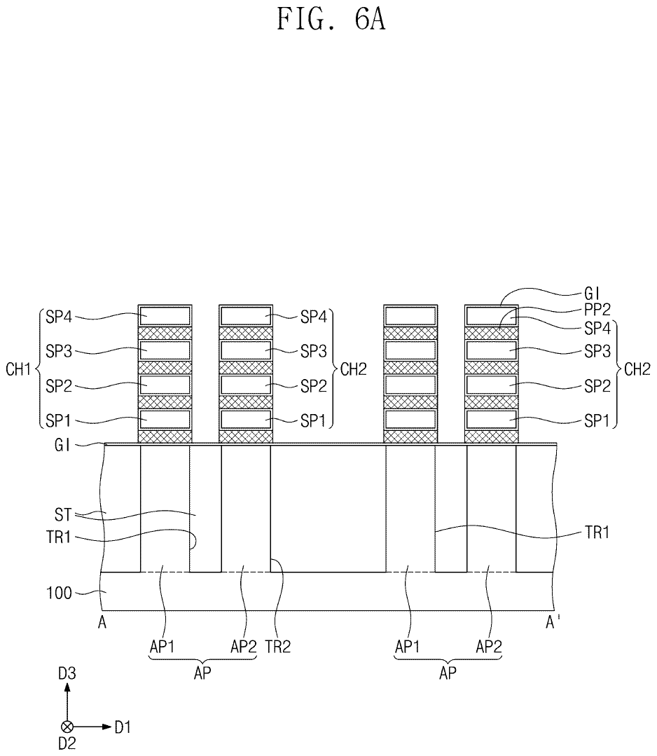

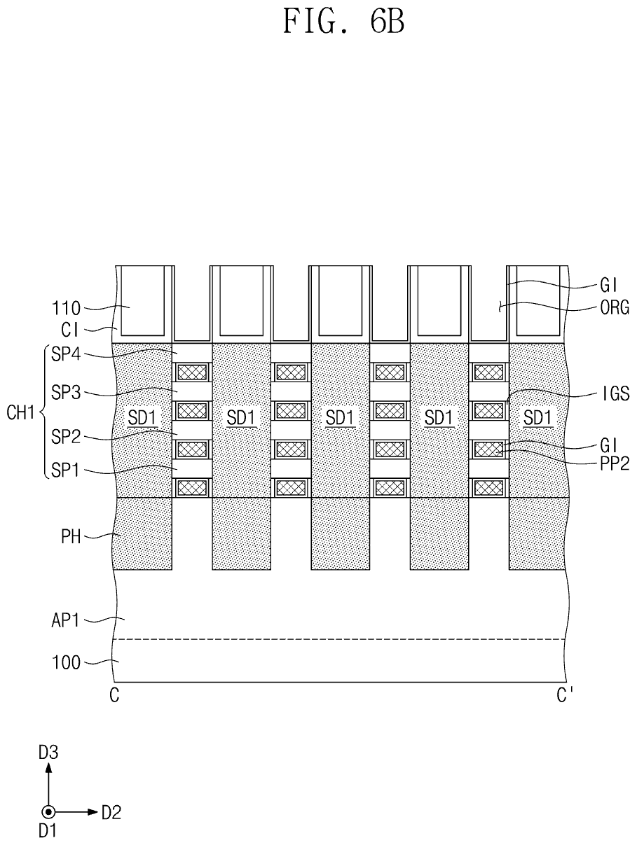

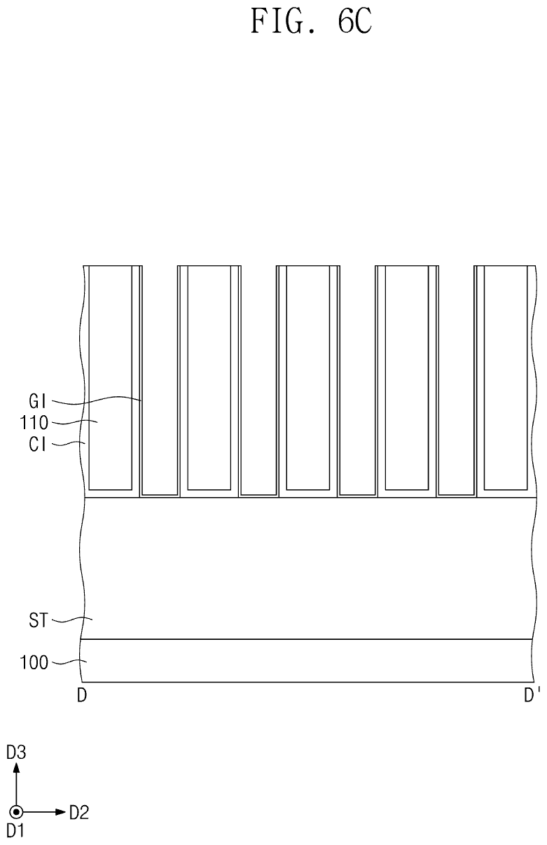

In FIGS. 6A, 6B, and 6C, the inner gate spacers IGS may be formed in the inner regions IRG. The inner gate spacers IGS may be located between the first source/drain patterns SD1 (or the second source/drain pattern SD2) and may be in contact with the first source/Drain patterns SD1 (or the second source/Drain pattern SD2). For example, the inner gate spacers IGS may include silicon oxide and a low-k material.

After the inner gate spacers IGS are formed, the gate insulating layer GI may be formed with a uniform thickness in the inner regions IRG and the outer region ORG. The gate insulating layer GI may cover the first and second channel patterns CH1 and CH2, the active patterns AP, the device isolation pattern ST, and the capping insulating layer CI. For example, the gate insulating layer GI may surround each of the first to fourth semiconductor patterns SP1, SP2, SP3, and SP4 of the first and second channel patterns CH1 and CH2.

After the gate insulating layer GI is formed, second sacrificial patterns PP2 may be formed between the first to fourth semiconductor patterns SP1, SP2, SP3, and SP4 of the first and second channel patterns CH1 and CH2. Forming the second sacrificial patterns PP2 may include forming a sacrificial layer on the substrate 100, and performing a wet etching process to partially remove the sacrificial layer.

The sacrificial layer may fill the inner regions IRG between the first to fourth semiconductor patterns SP1, SP2, SP3, and SP4. The sacrificial layer may be formed with a uniform thickness in a remaining region other than the inner regions IRG. As a result, a difference in the etching rate of the sacrificial layer between the inner regions IRG and the remaining region. Accordingly, a portion of the sacrificial layer between the first to fourth semiconductor patterns SP1, SP2, SP3, and SP4 may remain to form the second sacrificial patterns PP2.

According to some implementations, the second sacrificial patterns PP2 may include a material having an etching selectivity with the first layer PL1 and a second layer PL2 described below. For example, the second sacrificial patterns PP2 may include at least one of TiN, AlO, SiN, and the like.

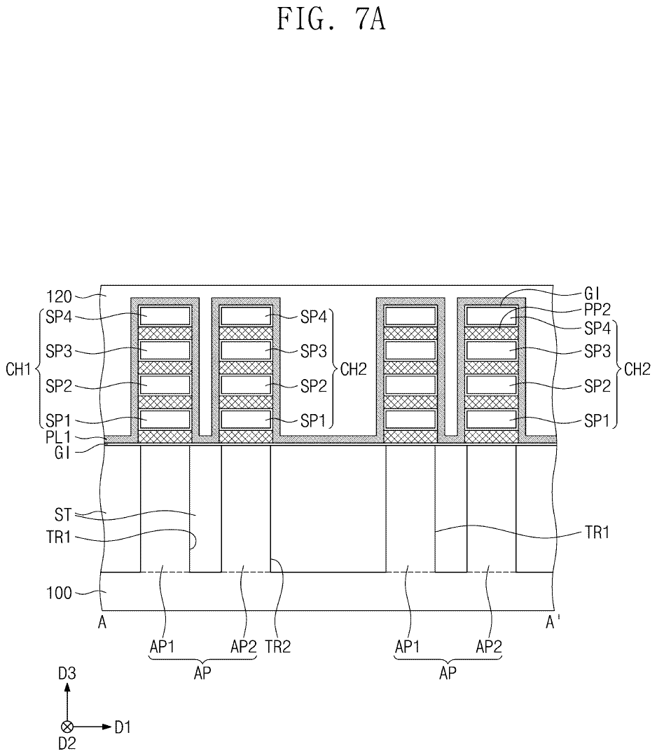

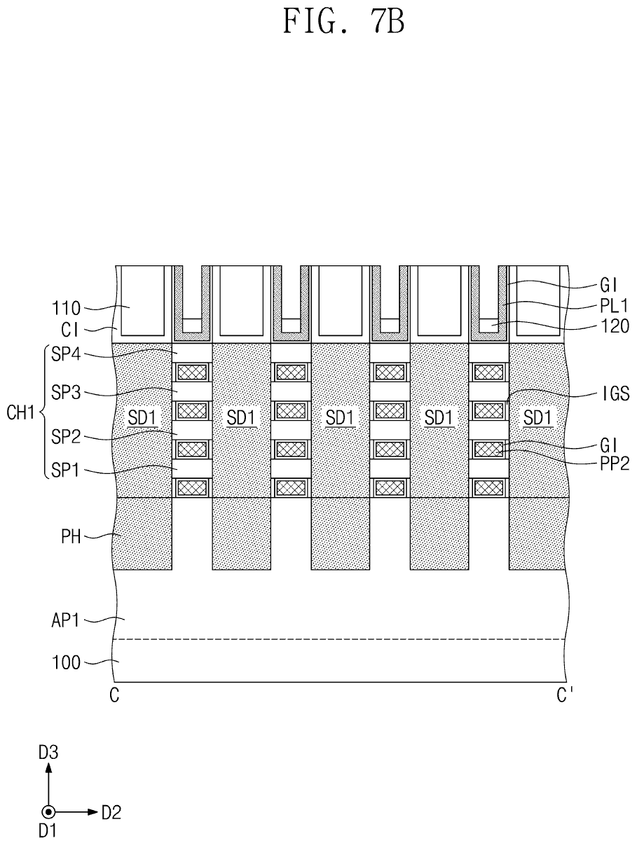

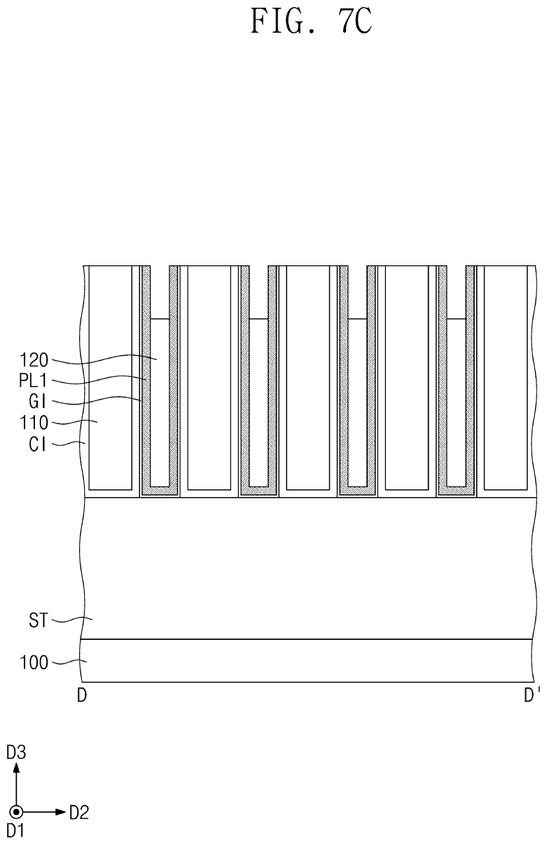

In FIGS. 7A, 7B, and 7C, a first layer PL1 may be formed on the substrate 100. The first layer PL1 may extend on the upper surface of the device isolation pattern ST and the side surface of the upper insulating patterns 110 on the first and second channel patterns CH1 and CH2. The first layer PL1 may be partially in contact with the gate insulating layer GI and the second sacrificial patterns PP2. The first layer PL1 may be formed with a uniform thickness. For example, a thickness of the first layer PL1 may be about 1 nm to about 5 nm.

According to some implementations, the first layer PL1 may include a material having an etching selectivity with the second sacrificial patterns PP2. For example, the first layer PL1 may include at least one of silicon oxide, silicon nitride, silicon oxynitride, silicon carbonite, and the like.

First preliminary insulation patterns 120 may be formed on the first layer PL1. Forming the first preliminary insulation patterns 120 may include performing a planarization process on the first preliminary insulation pattern 120. Due to the planarization process, upper surfaces of the first preliminary insulation patterns 120 may be located at a lower level than the upper surfaces of top insulation patterns 110. As a result, a portion of the first layer PL1 may be exposed by the first preliminary insulation patterns 120.

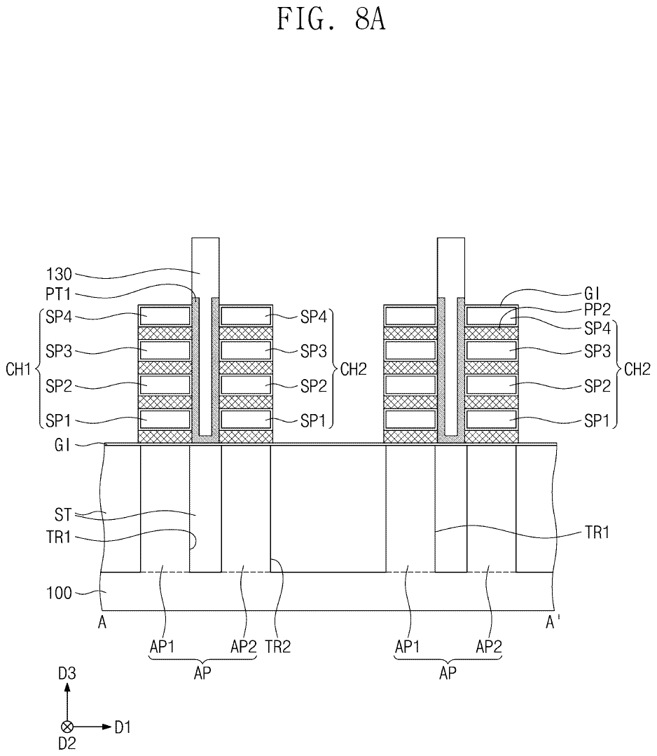

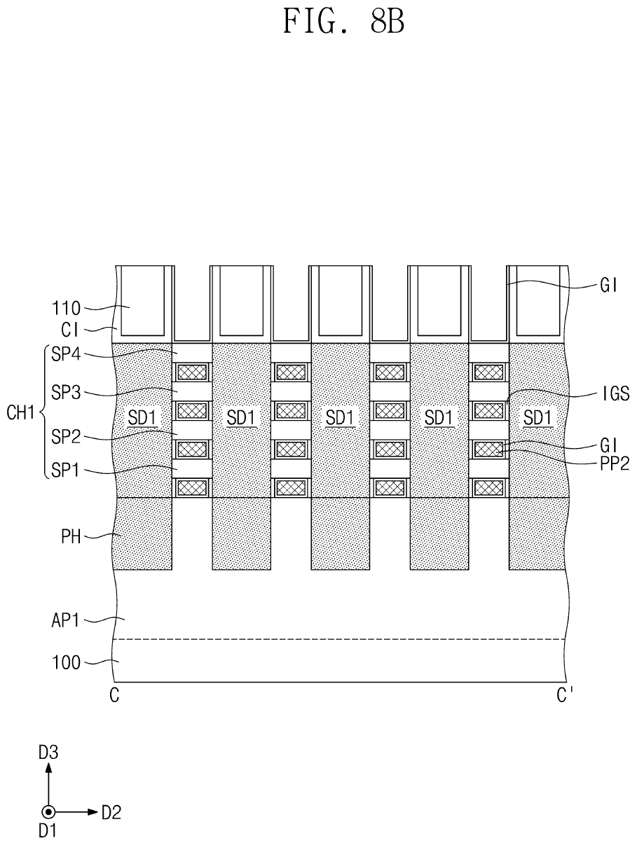

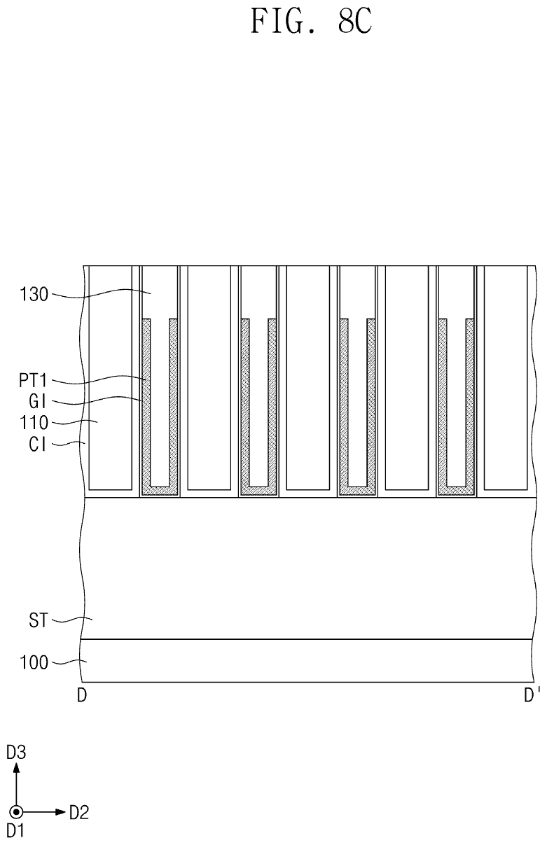

In FIGS. 8A, 8B, and 8C, an etching process may be performed on the first layer PL1. A portion of the first layer PL1 exposed by the first preliminary insulating patterns 120 may be removed by an etching process. As a result, the height of the first layer PL1 between the upper insulation patterns 110 may be reduced.

The first preliminary insulation patterns 120 may be removed and the second preliminary insulation patterns 130 may be formed. The second preliminary insulating patterns 130 may be located between the first and second channel patterns CH1 and CH2 and on the first layer PL1. The second preliminary insulating patterns 130 may expose other portion of the first layer PL1 covering the first and second channel patterns CH1 and CH2 and the element isolation pattern ST. For example, the second preliminary insulation patterns 130 may not overlap the first and second channel patterns CH1 and CH2, but are not limited thereto.

An etching process using the second preliminary insulating patterns 130 as a mask may be performed. The other portion of the first layer PL1 exposed by the second preliminary insulating patterns 130 may be removed by an etching process. As a result, a portion of the first layer PL1 remaining between the first and second channel patterns CH1 and CH2 may be formed as the first pattern PT1. For example, the first pattern PT1 may have a cylindrical shape with an inner surface.

The first pattern PT1 may have the first upper surface PT1U1 between the first and second channel patterns CH1 and CH2 described with reference to FIG. 3A and the second upper surface PT1U2 between the upper insulation patterns 110 described with reference to FIG. 3B. As a result, the first pattern PT1 may have upper surfaces of different levels.

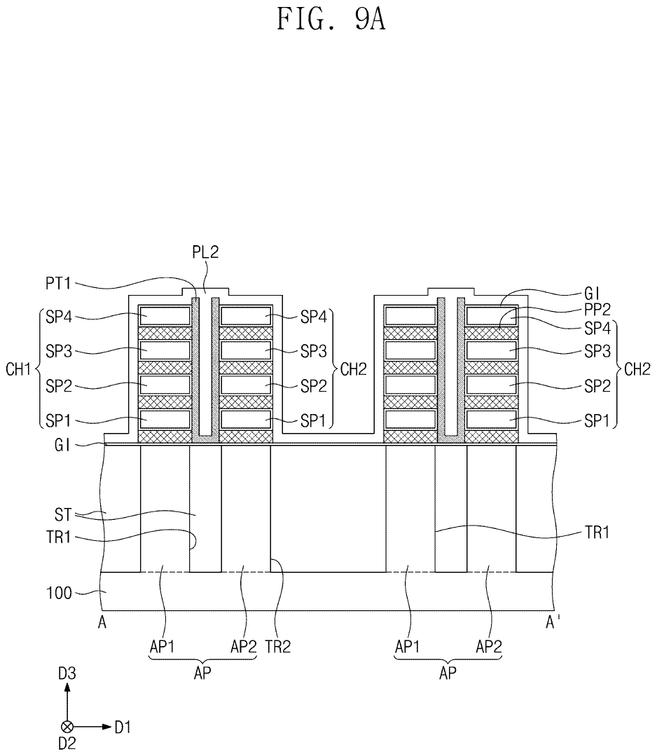

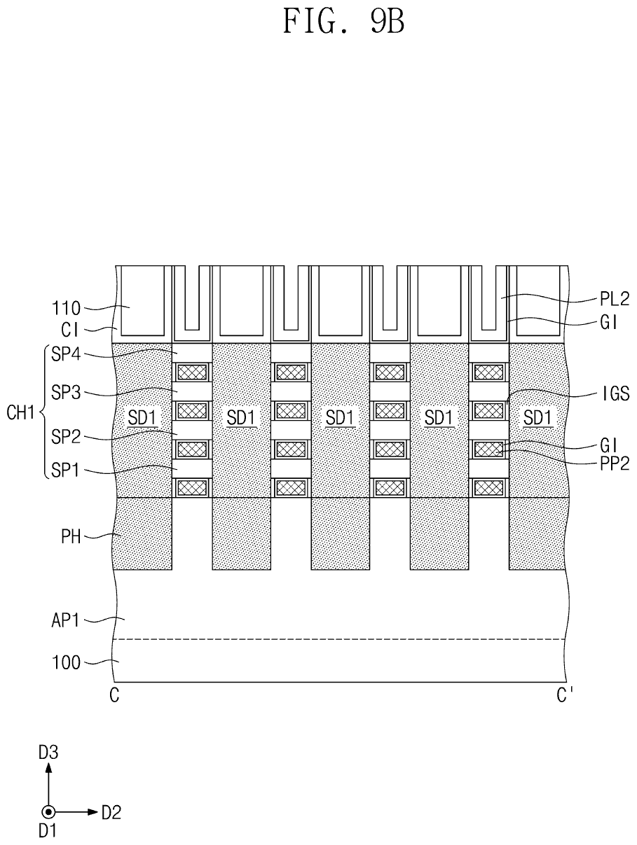

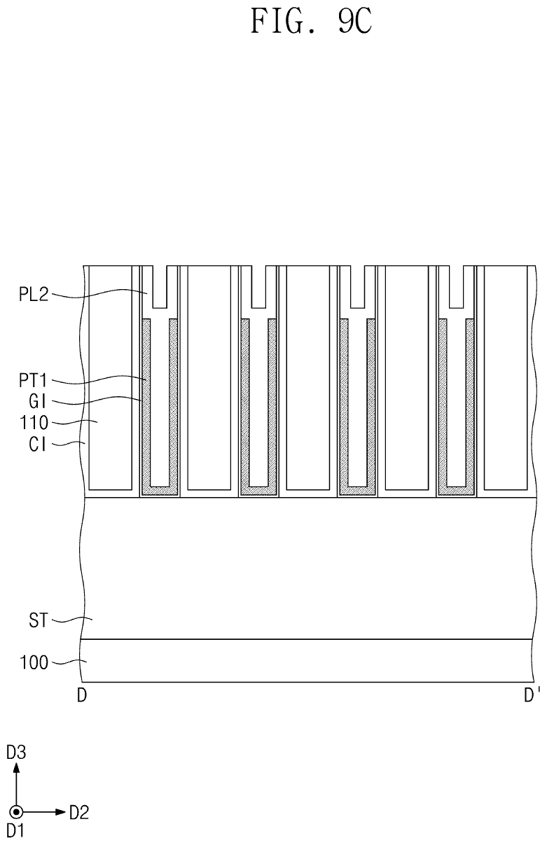

In FIGS. 9A, 9B, and 9C, the second preliminary insulating patterns 130 may be removed and the second layer PL2 may be formed on the substrate 100. The second partial PL2 may be formed to a uniform thickness by a deposition process. A thickness of the second layer PL2 may be greater than the thickness of the first layer PL1 described above. For example, the thickness of the second layer PL2 may be about 2 nm to about 5 nm.

More specifically, the second layer PL2 may be formed with the uniform thickness on the first and second channel patterns CH1 and CH2 and the device isolation pattern ST. In some implementations, the second layer PL2 may completely fill the inner surface of the first pattern PT1. As a result, a difference in the etching rate of the second layer PL2 between the inside and the outside of the first pattern PT1 may occur.

According to some implementations, the second layer PL2 may include a material having an etching selectivity with respect to the second sacrificial patterns PP2. For example, the second layer PL2 may include at least one of silicon oxide, silicon nitride, silicon oxynitride, silicon carbonite, and the like different from the first layer PL1.

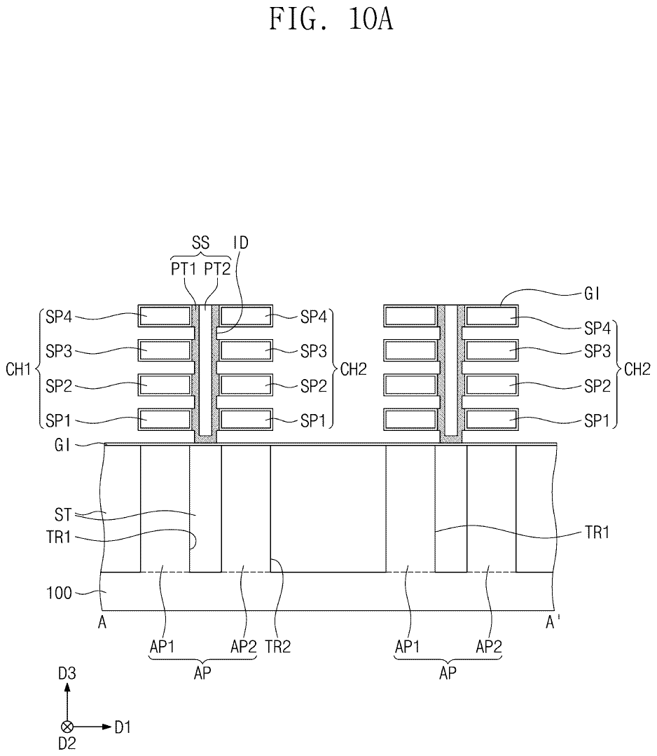

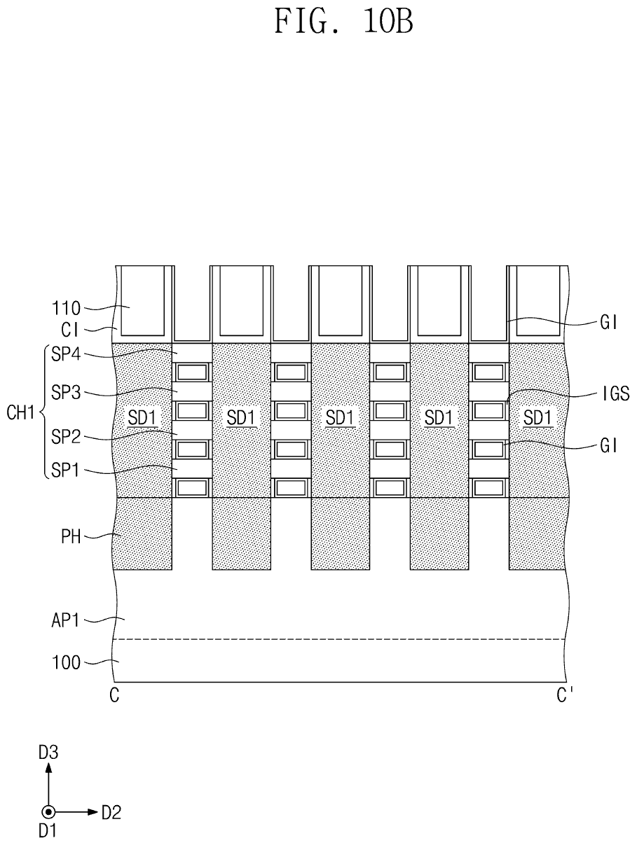

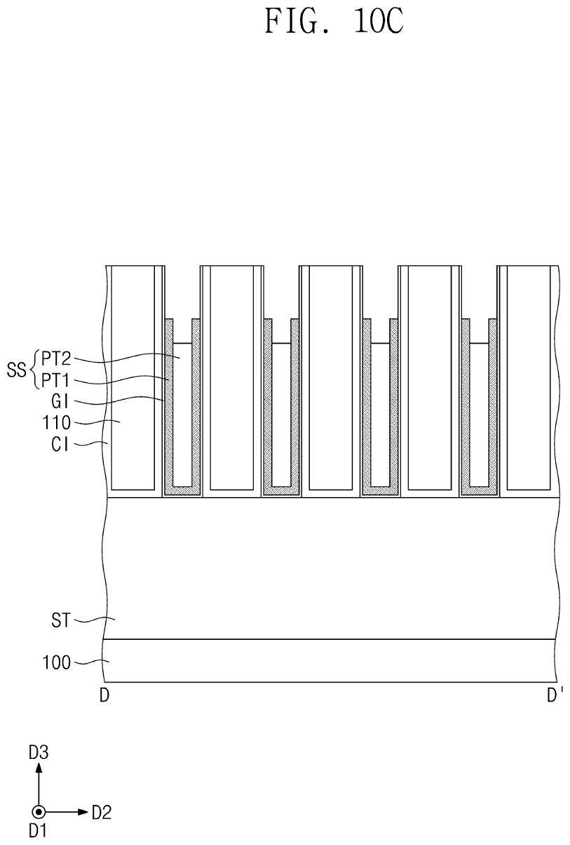

In FIGS. 10A, 10B, and 10C, an etching process may be performed on the second layer PL2. A portion of the second layer PL2 may be removed by an etching process. For example, the etching process may be a wet etching process that selectively removes the second layer PL2. As described above, the second layer PL2 has a different exposed area between the inside and the outside of the first pattern PT1, a difference in etching rate may occur. Accordingly, a portion of the second layer PL2 in the first pattern PT1 may remain and be formed into the second pattern PT2. Accordingly, the separating structures SS each including the first pattern PT1 and the second pattern PT2 may be formed.

The second pattern PT2 may have a columnar shape in the first pattern PT1. The upper surface of the second pattern PT2 may be coplanar with the first upper surface PT1U1 of the first pattern PT1 of FIG. 3A. The upper surface of the second pattern PT2 may be located at a lower level than the second upper surface PT1U2 of the first pattern PT1 of FIG. 3B. A portion of the first pattern PT1 may extend from the second pattern PT2 in the third direction D3. As a result, the portion of the first pattern PT1 may be exposed by the second pattern PT2.

According to some implementations, the second pattern PT2 may include protrusion portion as described with reference to FIG. 3E. In addition, the etching process may remove a portion of the first pattern PT1 together while removing the second pattern PT2.

An etching process may then be performed to selectively remove the second sacrificial patterns PP2. The inner regions IRG between the first to fourth semiconductor patterns SP1, SP2, SP3, and SP4 of the first and second channel patterns CH1 and CH2 may be exposed again. The first and second patterns PT1 and PT2 may include a material having an etch selectivity with respect to the second sacrificial patterns PP2, so that the first and second pattern PT1 and PT2 may not be removed.

After the second sacrificial patterns PP2 are removed, a portion of the first pattern PT1 may be removed to form indented regions ID. The first pattern PT1 may be recessed from the side surface of the first pattern PT1, which is exposed by the inner regions IRG, towards the second pattern PT2.

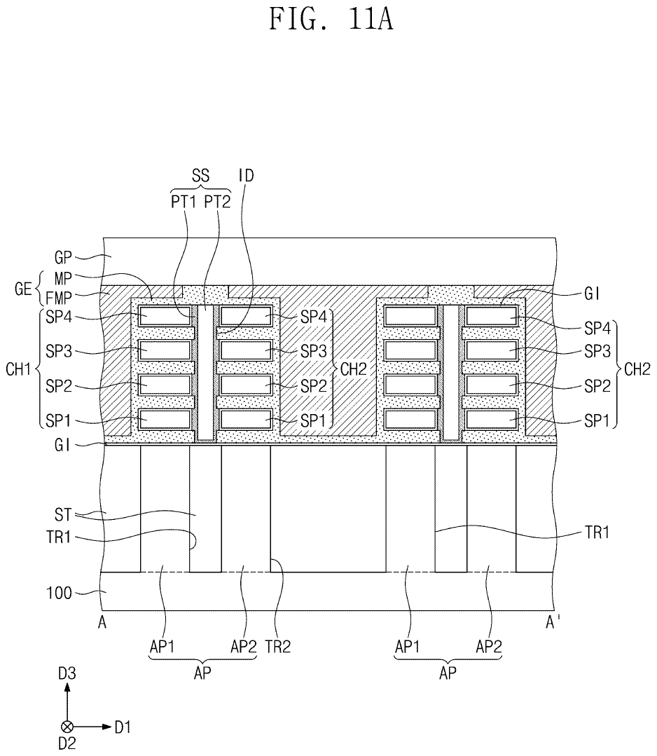

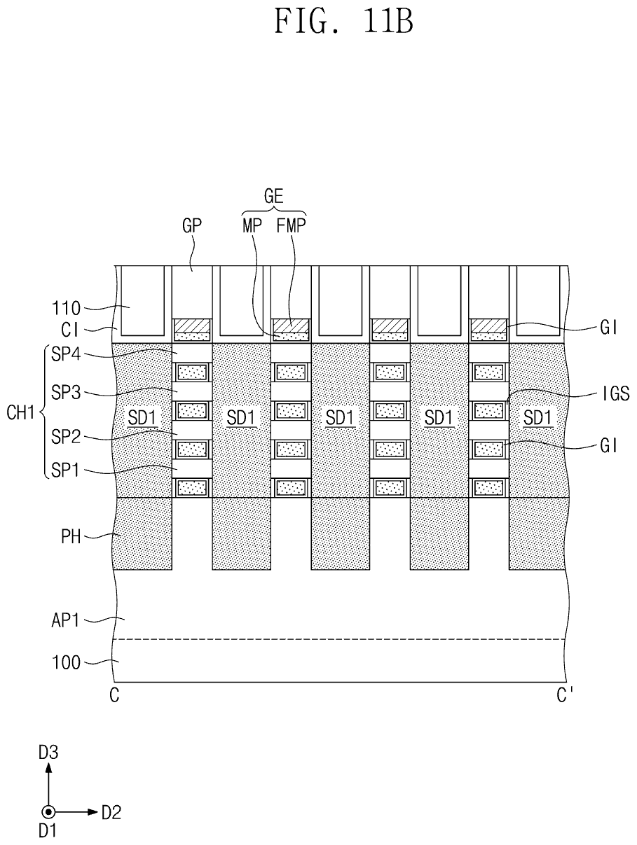

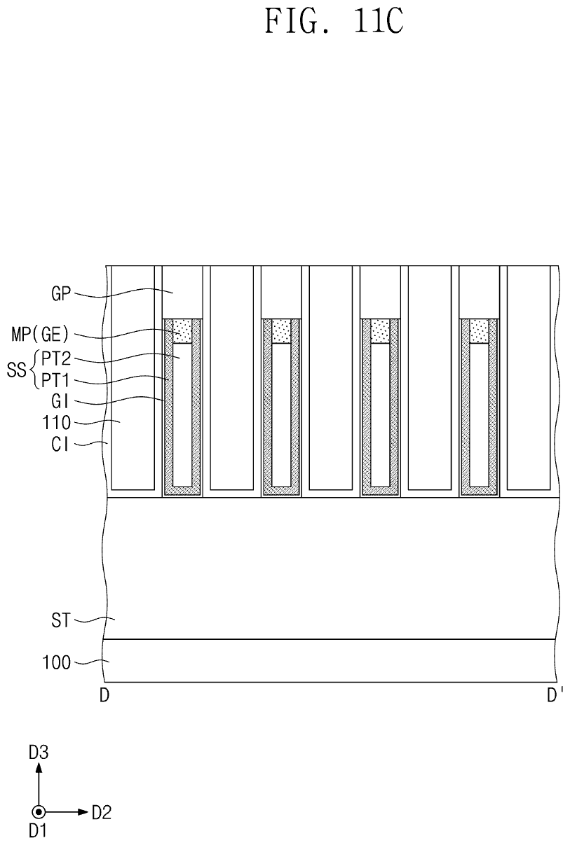

In FIGS. 11A, 11B, and 11C, gate electrodes GE may be formed on the first and second channel patterns CH1 and CH2, the separation structures SS. Forming the gate electrodes GE may include forming a metal pattern MP, and forming a filling metal pattern FMP on the metal pattern MP. For example, the metal pattern MP may be formed with a uniform thickness.

The metal pattern MP may be provided between the first to fourth semiconductor patterns SP1, SP2, SP3, and SP4 of the first and second channel patterns CH1 and CH2, and fill the inner regions IRG. The metal pattern MP may protrude upwards in a region overlapping with the separating structures SS by the portion of the first pattern PT1 extending from the second pattern PT2 of the separating structures SS. For example, the metal pattern MP may be in lower level in a portion overlapping with the first and second channel patterns CH1 and CH2, and in higher level in a portion overlapping with the separation structures SS.

The filling metal pattern FMP may cover the metal pattern MP and fill the space on the active patterns AP. Then, a planarization process may be performed on the gate electrodes GE. The planarization process may decrease the height of the upper surfaces of the gate electrodes GE. For example, the upper surfaces of the gate electrodes GE may be lower than the upper surfaces of upper insulating patterns 110.

Gate capping patterns GP may be formed on the gate electrodes GE. A planarization process may be performed on the gate capping patterns GP such that upper surfaces of the gate capping pattern GP may be coplanar with upper surfaces of the upper isolation patterns 110.

In FIGS. 12A, 12B, and 12C, a mask pattern HMP having openings OP may be formed on the gate capping patterns GP. Each of the openings OP of the mask pattern HMP may overlap with at least one of the separation structures SS. For example, some of the separation structures SS may overlap with the openings OP of the mask pattern HMP, and others of the separation structures SS may not overlap with openings OP of the mask pattern HMP.

A number and arrangement of the openings OP of the mask pattern HMP of the inventive concept may be variously provided. For example, each of the openings OP of the mask pattern HMP may overlap with each of all the separation structures SS. In some implementations, only one of the separation structures SS adjacent in the first direction D1 may overlap with the openings OP of the mask pattern HMP.

Then, an etching process using the mask pattern HMP may be performed. The etching process may partially remove the gate capping patterns GP and the gate electrodes GE to expose the upper surfaces of the separation structures SS.

In FIGS. 2A, 2B, 2C, and 2D, first gate cutting patterns CT1 may be formed that fill the gate capping patterns GP and the gate electrodes GE. For example, the first gate cutting patterns CT1 may be formed in a self-aligned manner by the portion of the first pattern PT1 extending further onto the second pattern PT2 of the separation structures SS. Each of the first gate cutting patterns CT1 may be in contact with each of the separation structures SS.

A second gate cutting pattern CT2 may be formed between the active patterns AP, penetrating the gate capping patterns GP and the gate electrodes GE. The second gate cutting pattern CT2 may further extend into the device isolation pattern ST. In a plan view, the second gate cutting pattern CT2 may extend in the second direction D2.

Active contacts AC may be formed in the upper isolation patterns 110 and gate contacts GC may be formed in gate capping patterns GP. Each of the active contacts AC may be connected with at least one of the first and second source/drain patterns SD1 and SD2, and penetrate the first upper insulating patterns 110. Each of the gate contacts GC may be connected with the gate electrodes GE, and penetrate the gate capping patterns GP.

A metal layer ML may be formed on the upper insulating patterns 110 and the gate capping patterns GP. Forming the metal layer ML may include forming a wiring structure that connects with the active contacts AC and the gate contacts GC.

In some implementations, the method for manufacturing a semiconductor element may include forming the separation structures SS each including the first pattern PT1 and the second pattern PT2 before forming the gate electrodes GE. The portion of the first pattern PT1 vertically extends from the second pattern PT2, so that the gate electrodes GE may be formed with a narrow width. Accordingly, the first gate cutting patterns CT1 electrically separating the gate electrodes GE are formed in a small size, and to prevent the parasitic capacitors due to remaining portions of the gate electrodes GE. Accordingly, the electrical characteristics and the integration of the semiconductor device may be improved.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a first channel pattern and a second channel pattern spaced apart from each other on a substrate;
a separation structure between the first channel pattern and the second channel pattern; and
a gate electrode on the first channel pattern, the second channel pattern, and the separation structure;
wherein the separation structure comprises:
a first pattern adjacent to the first channel pattern and the second channel pattern; and
a second pattern between the first channel pattern and the second channel pattern,
wherein a portion of an upper surface of the first pattern is located higher than an upper surface of the second pattern.

2. The semiconductor device of claim 1, comprising:
a gate cutting pattern on the separation structure,
wherein the gate cutting pattern contacts the upper surface of the second pattern.

3. The semiconductor device of claim 2, wherein a lower side surface of the gate cutting pattern contacts the first pattern.

4. The semiconductor device of claim 2, wherein the gate cutting pattern has a circular or elliptical shape.

5. The semiconductor device of claim 1, wherein the first channel pattern and the second channel pattern include a plurality of semiconductor patterns spaced apart from each other in a vertical direction.

6. The semiconductor device of claim 5, wherein the upper surface of the second pattern of the separation structure is located higher than a lower surface of an uppermost semiconductor pattern of the plurality of semiconductor patterns.

7. The semiconductor device of claim 5, wherein the first pattern of the separation structure has indented regions recessed toward the second pattern on a side surface of the first pattern.

8. The semiconductor device of claim 5, comprising:
a gate insulating layer between the gate electrode and the plurality of semiconductor patterns,
wherein the gate insulating layer surrounds a plurality of surfaces of each of the plurality of semiconductor patterns.

9. The semiconductor device of claim 1, wherein the second pattern of the separation structure includes a protrusion portion extending into the gate electrode.

10. The semiconductor device of claim 1,
wherein a first portion of the gate electrode that overlaps the first channel pattern and the second channel pattern has a first width, and
wherein a second portion of the gate electrode that overlaps the separation structure has a second width smaller than the first width.

11. A semiconductor device comprising:
active patterns on a substrate;
channel patterns including a plurality of semiconductor patterns on the active patterns;
a separation structure between the channel patterns;
a gate electrode on the channel patterns and the separation structure;
a first gate cutting pattern overlapping the separation structure; and
a second gate cutting pattern spaced apart from the first gate cutting pattern and extending into the gate electrode,
wherein the separation structure includes a first pattern adjacent to the channel patterns and a second pattern spaced apart from the channel patterns, and
wherein an uppermost surface of the first pattern is coplanar with an upper surface of the gate electrode.

12. The semiconductor device of claim 11,
wherein the first pattern has a cylindrical shape, and
wherein the second pattern has a columnar shape in the first pattern.

13. The semiconductor device of claim 11, wherein the first gate cutting pattern contacts the first pattern and the second pattern.

14. The semiconductor device of claim 11, wherein a vertical length of the first gate cutting pattern is less than a vertical length of the second gate cutting pattern.

15. The semiconductor device of claim 11, wherein a lower surface of the first gate cutting pattern is located lower than the uppermost surface of the first pattern.

16. The semiconductor device of claim 11, wherein the uppermost surface of the first pattern is located higher than an upper surface of the second pattern.

17. The semiconductor device of claim 11, wherein the first gate cutting pattern is aligned with the first pattern.

18. A semiconductor device comprising:
a first active pattern and a second active pattern spaced apart from each other on a substrate;
first channel patterns on the first active pattern,
second channel patterns on the second active pattern;
first source/drain patterns between the first channel patterns and second source/drain patterns between the second channel patterns;
separation structures between the first channel patterns and the second channel patterns;
gate electrodes on the first channel patterns, second channel patterns, and the separation structures;
gate capping patterns on the gate electrodes;
a first gate cutting pattern on at least one separation structure of the separation structures; and
a second gate cutting pattern spaced apart from the separation structures and extending into the gate electrodes,
wherein the separating structures include a first pattern and a second pattern, the second pattern being disposed inside the first pattern, and
wherein the first pattern extends from the second pattern to a lower side surface of the first gate cutting pattern.

19. The semiconductor device of claim 18,
wherein the first gate cutting pattern has a circular or elliptical shape, and
wherein the second gate cutting pattern extends in a second direction intersecting the first direction.

20. The semiconductor device of claim 18,
wherein the first pattern has upper surfaces of different levels, and
wherein an uppermost surface of the first pattern is higher than an upper surface of the second pattern and a lower surface of the first gate cutting pattern.
